(19) United States
(12) Patent Application Publication
(10) Pub. No.: US 2026/0311770 A1
(43) Pub. Date: Oct. 8, 2026

(54) STORAGE DEVICE UPDATING OPERATION VOLTAGES BASED ON A NUMBER OF OFF CELLS AND METHOD OF OPERATING THE SAME

(71) Applicant: Samsung Electronics Co., Ltd., Suwon-si (KR)

(72) Inventors: HYOJIN AHN, Suwon-si (KR); JEONGYEOL KIM, Suwon-si (KR); Dongwoo Shin, Suwon-si (KR)

(21) Appl. No.: 19/458,161

(22) Filed: Jan. 23, 2026

(30) Foreign Application Priority Data
Apr. 8, 2025 (KR) 10-2025-0045563

(51) Int. Cl. G11C 16/14; G11C 16/04; G11C 16/08; G11C 16/10; G11C 16/26

(52) U.S. Cl. CPC G11C 16/14; G11C 16/0483; G11C 16/08; G11C 16/10; G11C 16/26

(57) ABSTRACT

A method of operating a storage device includes applying a first erase voltage to a first memory block, among a plurality of memory blocks, in response to a first erase command for the first memory block, determining a number of off-cells, each having a threshold voltage greater than or equal to a reference voltage, among memory cells included in the first memory block, obtaining a second erase voltage by adding a unit erase voltage to the first erase voltage in response to the number of the off-cells exceeding a reference number, and applying the second erase voltage to the first memory block in response to a second erase command for the first memory block.

### CROSS-REFERENCE TO RELATED APPLICATIONS

This U.S. non-provisional application claims priority under 35 USC § 119 to Korean Patent Application No. 10-2025-0045563, filed on Apr. 8, 2025, in the Korean Intellectual Property Office, the disclosure of which is herein incorporated by reference in its entirety.

### BACKGROUND

The present disclosure relates to a storage device and a method of operating the same.

Semiconductor memory devices may be broadly divided into volatile memory devices and non-volatile memory devices. Volatile memory devices offer high read and write speeds but have the disadvantage of losing stored data when their power supplies are interrupted, while non-volatile memory devices retain their stored data even when their power supplies are interrupted. Therefore, non-volatile memory devices are used to store data that needs to be preserved regardless of whether power is supplied.

A flash memory device is a representative example of a non-volatile memory device. Flash memory devices are widely used as storage media for voice and image data in information devices such as computers, mobile phones, smartphones, personal digital assistants (PDAs), digital cameras, camcorders, voice recorders, MP3 players, handheld personal computer (PCs), gaming consoles, fax machines, scanners, or printers.

The characteristics of flash memory devices may change depending on various factors, such as the usage environment, frequency of use, or duration of use. For example, as the number of uses of a flash memory device increases, characteristics of the flash memory may change, requiring an operating voltage that matches the changed characteristics.

Accordingly, research has been conducted into methods for controlling an operating voltage of a flash memory device based on a change in characteristics of the flash memory device.

### SUMMARY

The present disclosure provides a storage device configured to adaptively control the magnitude of an operating voltage based on threshold voltage distribution of memory cells, and a method of operating the same.

According to an aspect of the present disclosure, a method of operating a storage device includes applying a first erase voltage to a first memory block, among a plurality of memory blocks, in response to a first erase command for the first memory block, determining a number of off-cells, each having a threshold voltage greater than or equal to a reference voltage, among memory cells included in the first memory block, obtaining a second erase voltage by adding a unit erase voltage to the first erase voltage in response to the number of the off-cells exceeding a reference number, and applying the second erase voltage to the first memory block in response to a second erase command for the first memory block.

According to an aspect of the present disclosure, a storage device includes a memory device including a plurality of memory blocks and a memory controller configured to control an erase operation, a program operation, and a read operation on the memory device. The memory controller may be configured to apply a first erase voltage to memory cells included in a first memory block in response to a first erase command for the first memory block, determine a number of off-cells, each having a threshold voltage greater than or equal to a reference voltage, among the memory cells, obtain a second erase voltage by adding a unit erase voltage to the first erase voltage in response to the number of the off-cells exceeding a reference number, and apply the second erase voltage to the memory cells in response to a second erase command for the first memory block.

According to an aspect of the present disclosure, a method of operating a storage device includes applying a first erase voltage to memory cells included in a first memory block among a plurality of memory blocks in response to a first erase command for the first memory block, applying a first program voltage through a first wordline connected to a first page to memory cells included in the first page in the first memory block in response to a first program command for the first page, determining a number of off-cells, each having a threshold voltage greater than or equal to a reference voltage, among the memory cells included in the first memory block, obtaining a second program voltage by subtracting a unit program voltage from the first program voltage in response to the number of the off-cells exceeding a reference number, and applying the second program voltage through the first wordline in response to a second program command for the memory cells included in the first page.

### BRIEF DESCRIPTION OF DRAWINGS

FIG. 1 is a block diagram of a memory system according to one or more embodiments.

FIG. 2 is a block diagram of a storage device according to one or more embodiments.

FIG. 3 is a block diagram of a memory device according to one or more embodiments.

FIG. 4 is a circuit diagram illustrating a first memory block among a plurality of memory blocks according to one or more embodiments.

FIG. 5 is a diagram illustrating a configuration in which a memory controller according to one or more embodiments applies a first erase voltage to a first memory block.

FIG. 6 is a diagram illustrating a configuration in which a memory controller according to one or more embodiments determines the number of memory cells, each having a threshold voltage greater than or equal to a first reference voltage.

FIG. 7 is a diagram illustrating a configuration in which a memory controller according to one or more embodiments applies a second erase voltage to a first memory block.

FIG. 8 is a diagram illustrating a configuration in which a memory controller according to one or more embodiments applies a first program voltage through a first wordline.

FIG. 9 is a diagram illustrating a configuration in which a memory controller according to one or more embodiments determines the number of memory cells, each having a threshold voltage greater than or equal to a second reference voltage.

FIG. 10 a diagram illustrating a configuration in which a memory controller according to one or more embodiments applies a second program voltage through a first wordline.

FIG. 11 is a diagram illustrating a configuration in which a memory controller according to one or more embodiments applies a first read voltage through a first wordline.

FIG. 12 is a diagram illustrating a configuration in which a memory controller according to one or more embodiments generates a first read voltage from a pre-read voltage.

FIG. 13 a diagram illustrating a configuration in which a memory controller according to one or more embodiments applies a first batch erase voltage to a first super block.

FIG. 14 is a diagram illustrating a configuration in which a memory controller according to one or more embodiments applies a second batch erase voltage to a first super block.

FIG. 15 is a flowchart illustrating a method, performed by a storage device according to one or more embodiments, of controlling the magnitude of an erase voltage based on threshold voltages of memory cells.

FIG. 16 is a flowchart illustrating a method, performed by a storage controller according to one or more embodiments, of controlling the magnitude of an erase voltage based on threshold voltages of memory cells after performing a program operation.

FIG. 17 is a flowchart illustrating a method, performed by a storage device according to one more embodiments, of controlling the magnitude of a program voltage based on threshold voltages of memory cells after performing a program operation.

FIG. 18 is a flowchart illustrating a method, performed by a storage device according to one or more embodiments, of controlling the magnitude of a read voltage based on threshold voltages of memory cells.

FIG. 19 is a flowchart illustrating a method, performed by a storage device according to one or more embodiments, of controlling the magnitude of a batch erase voltage applied to a super block based on threshold voltages of memory cells.

FIG. 20 is a block diagram illustrating an example in which a storage device according to one or more embodiments is implemented as a solid state drive (SSD).

FIG. 21 is a diagram illustrating a flash memory according to one or more embodiments.

### DETAILED DESCRIPTION

The following description with reference to the accompanying drawings is provided to assist in a comprehensive understanding of various embodiments of the present disclosure.

The term "first," "second," or the like used herein may modify various elements regardless of the order and/or priority thereof, and is used only for distinguishing one element from another element, without limiting example embodiments.

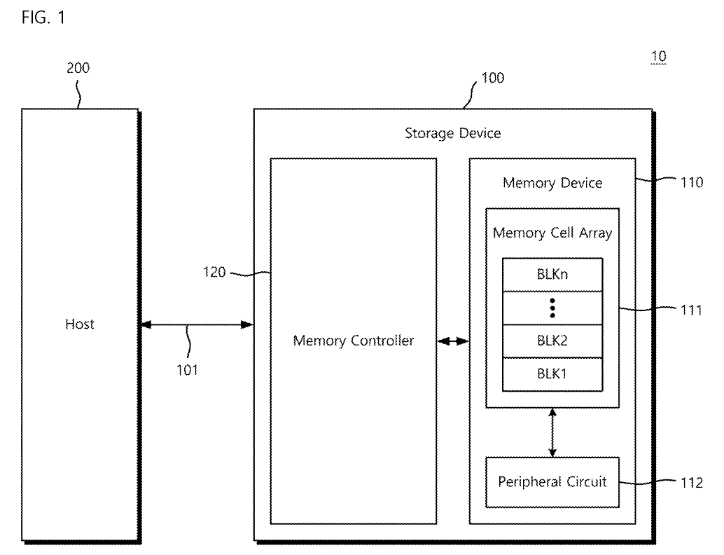

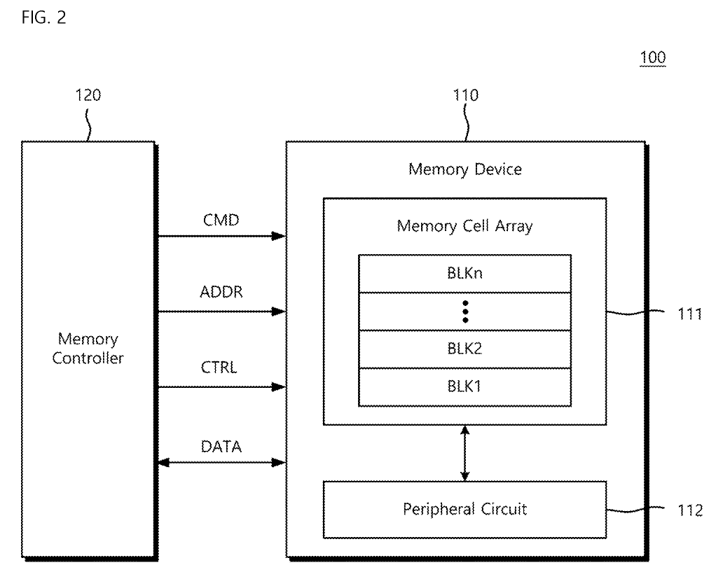

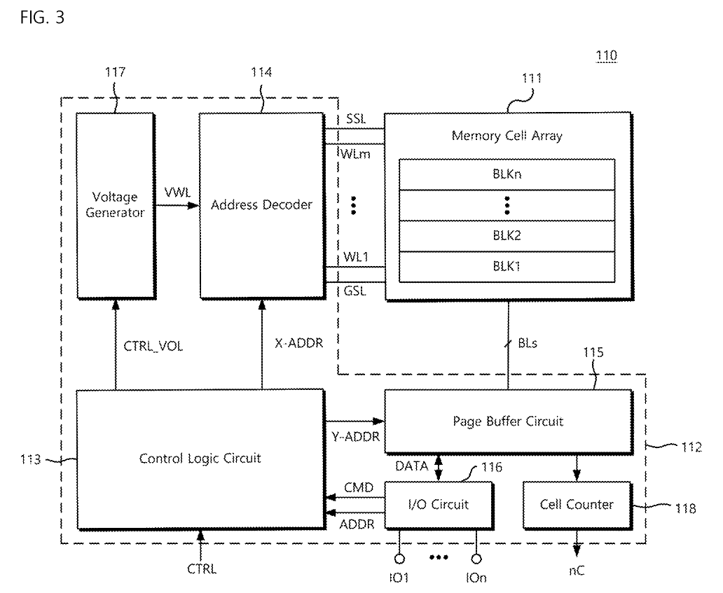

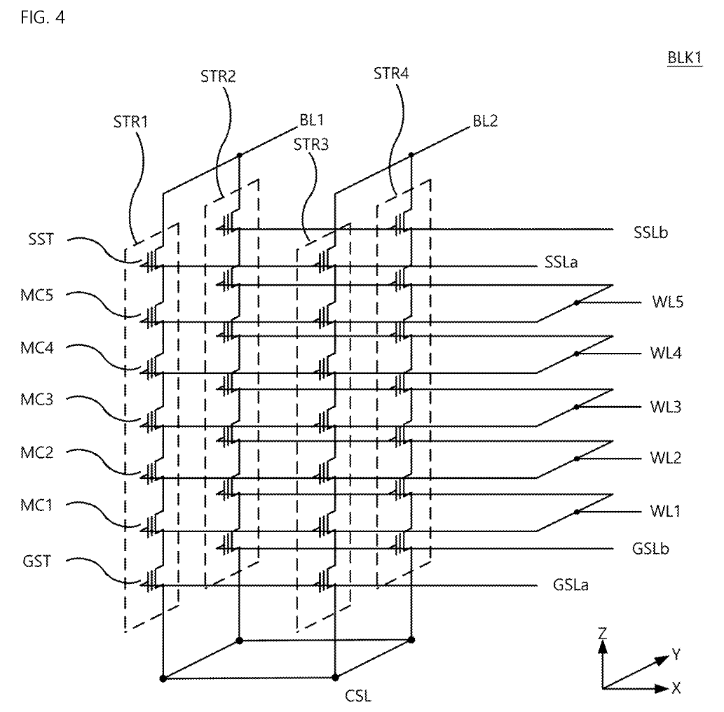

FIG. 1 is a block diagram of a memory system according to one or more embodiments. FIG. 2 is a block diagram of a storage device according to one or more embodiments. FIG. 3 is a block diagram of a memory device according to one or more embodiments. FIG. 4 is a circuit diagram illustrating a first memory block among a plurality of memory blocks according to one or more embodiments.

Referring to FIG. 1, a memory system 10 may include a storage device 100 and a host 200. The storage device 100 may be connected to the host 200 via a host interface 101.

The storage device 100 may be based on a non-volatile memory. For example, the storage device 100 may be a flash storage device. The flash storage device may include a solid state drive (SSD), a universal flash storage (UFS), or a memory card.

Referring to FIGS. 1 and 2, the storage device 100 may include a memory device 110 and a memory controller 120.

According to one or more embodiments, the storage device 100 may include the memory controller 120 that controls the memory device 110.

The memory controller 120 may control at least one other component (for example, a peripheral circuit 112) of the storage device 100 by executing software (or a program) and may perform various data processing or operations. The memory controller 120 may include a central processing unit or a microprocessor, and may control the overall operation of the storage device 100. Accordingly, operations performed by the storage device 100 may be understood to be performed under the control of the memory controller 120.

The storage device 100 may include a memory device 110 configured to store data.

For example, the memory device 110 may be referred to as a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), or the like. The memory device 110 may be implemented with a three-dimensional array structure. The memory device 110 according to one or more embodiments may be referred to as a flash memory device in which a charge storage layer includes a conductive floating gate, as well as a charge trap flash (CTF) in which a charge storage layer includes an insulating layer. For clarity, an example is provided in which the memory device 110 is a vertical NAND flash memory device (VNAND).

The memory device 110 may include a memory cell array 111 and a peripheral circuit 112.

According to one or more embodiments, the memory cell array 111 may include a plurality of memory blocks BLK1 to BLKn. Each memory block may have a vertical three-dimensional structure. Each memory block may include a plurality of memory cells.

In one example, multi-bit data may be stored in each memory cell. Each memory cell may be referred to as a multi-level cell (MLC).

In another example, single-bit data may be stored in each memory cell. Each memory cell may be referred to as a single-level cell (SLC).

The memory cell array 111 may be disposed next to or above the peripheral circuit 112 in terms of design layout. A structure in which the memory cell array 111 is disposed above the peripheral circuit 112 may be referred to as a cell on peripheral (COP) structure.

According to one or more embodiments, the memory cell array 111 and the peripheral circuit 112 may each be manufactured as separate chips. An upper chip including the memory cell array 111 and a lower chip including the peripheral circuit 112 may be connected to each other by a bonding method. Such a structure may be referred to as a chip-to-chip (C2C) structure.

According to one or more embodiments, the peripheral circuit 112 may receive external power from the memory controller 120 and generate various levels of internal power.

For example, referring to FIG. 2, the peripheral circuit 112 may receive a command CMD, an address ADDR, and data DATA from the memory controller 120. The peripheral circuit 112 may store data DATA in a memory cell specified by the address ADDR among the memory cell array 111, based on a control signal CTRL. The peripheral circuit 112 may read the data DATA stored in the memory cell specified by the address ADDR among the memory cell array 111 and provide the read data DATA to the memory controller 120.

Referring to FIGS. 2 and 3, the peripheral circuit 112 may include a control logic circuit 113, an address decoder 114, a page buffer circuit 115, an input/output circuit 116, a voltage generator 117, and a cell counter 118.

According to one or more embodiments, the memory cell array 111 may include a plurality of memory blocks BLK1 to BLKn (where n is an integer greater than or equal to 2). Each memory block may include a plurality of pages. Each page may include a plurality of memory cells. Each memory block may be a unit of an erase operation, and each page may be a unit of a read operation or a program operation.

According to one or more embodiments, the memory cell array 111 may be formed in a direction vertical to a substrate. A gate electrode layer and an insulation layer may be alternately deposited on the substrate. Each memory block (for example, a first memory block BLK1) may be connected to a string select line SSL, a plurality of wordlines WL1 to WLm (where m is an integer greater than or equal to 2), and a ground select line GSL.

For example, referring to FIG. 4, a first memory block BLK1 may include a plurality of memory strings STR1 to STR4 connected between bitlines BL1 and BL2 and a common source line CSL.

Each of the plurality of memory strings STR1 to STR4 may include a string select transistor SST, a plurality of memory cells MC1 to MC5, and a ground select transistor GST. In FIG. 4, each of the plurality of memory strings STR1 to STR4 is illustrated as including five memory cells MC1 to MC5, but embodiments are not limited thereto.

The string select transistor SST may be connected to corresponding string select lines SSLa and SSLb. The plurality of memory cells MC1 to MC5 may be connected to corresponding wordlines WL1 to WL5, respectively. A portion of the wordlines WL1 to WL5 may correspond to dummy wordlines.

The ground select transistor GST may be connected to corresponding ground select lines GSLa and GSLb. The string select transistor SST may be connected to corresponding bitlines BL1 and BL2, and the ground select transistor GST may be connected to the common source line CSL.

Wordlines at the same height (for example, a first wordline WL1) may be commonly connected, and the ground select lines GSLa and GSLb and the string select lines SSLa and SSLb may be separated, respectively. In FIG. 4, the first memory block BLK1 is illustrated as being connected to five wordlines WL1 to WL5 and two bitlines BL1 and BL2, embodiments are not limited thereto.

Each of the memory blocks BLK2 to BLKn, excluding the first memory block BLK1 among the plurality of memory blocks BLK1 to BLKn, may include substantially the same configuration as the first memory block BLK1.

Returning to FIG. 3, the control logic circuit 113 according to one or more embodiments may control a read operation, a program operation, an erase operation, or a verify operation of the memory device 110 using a command CMD, an address ADDR, and a control signal CTRL provided from the memory controller 120. The address ADDR may include a block select address for selecting one memory block, a row address X-ADDR for selecting a single page, and a column address Y-ADDR for selecting a single memory cell.

The address decoder 114 may be connected to the memory cell array 111 through the select lines SSL and GSL and the wordlines WL1 to WLm. The address decoder 114 may select a wordline during a program operation or a read operation. The address decoder 114 may receive a wordline voltage VWL from the voltage generator 117 and provide a program voltage or a read voltage to the selected wordline. For example, the address decoder 114 may provide a program voltage or a read voltage to a wordline specified by a row address X-ADDR received from the control logic circuit 113.

The page buffer circuit 115 may be connected to the memory cell array 111 through a plurality of bitlines BLs. The page buffer circuit 115 may temporarily store data to be stored in the memory cell array 111 or data read from the memory cell array 111.

The page buffer circuit 115 according to one or more embodiments may include a plurality of page buffers, respectively connected to the plurality of bitlines BLs. Each page buffer may include a plurality of latches for storing or reading multi-bit data. For example, the page buffer circuit 115 may control a page buffer connected to a bitline specified by a column address Y-ADDR received from the control logic circuit 113.

The input/output circuit 116 may be internally connected to the page buffer circuit 115 via a data line and externally connected to the memory controller 120 via input/output lines IO1 to IOn. The input/output circuit 116 may receive program data from the memory controller 120 during a program operation. The input/output circuit 116 may provide data read from the memory cell array 111 to the memory controller 120 during a read operation.

The voltage generator 117 may generate a wordline voltage VWL required for reading or writing data, based on a voltage control signal CTRL_VOL received from the control logic circuit 113. The wordline voltage VWL may be provided to a selected wordline sWL or an unselected wordline uWL via the address decoder 114.

The cell counter 118 may count memory cells, each having a threshold voltage falling within a specific voltage range, from data stored in the page buffer circuit 115.

For example, the cell counter 118 may count the number of memory cells, each having a threshold voltage within a specific range, by processing data stored in the page buffer circuit 115.

In one example, the cell counter 118 may be implemented as a circuit, separate from the control logic circuit 113. In another example, the cell counter 118 may be implemented inside the control logic circuit 113, or may be implemented as a single circuit with the control logic circuit 113.

The cell counter 118 may output a count result nC including the number of memory cells, each having a threshold voltage within a specific range, to the memory controller 120.

The memory controller 120 according to one or more embodiments may control the magnitude of an operating voltage applied for the operation of the memory device 110, based on the count result nC of the cell counter 118.

For example, the memory controller 120 may control the magnitude of the operating voltage in response to the number of memory cells among the plurality of memory cells included in the memory cell array 111, having a threshold voltage greater than or equal to a reference voltage, exceeding a reference number.

The reference voltage and the reference number may each be predetermined and stored in the memory device 110. For example, the memory controller 120 may control at least a portion of the reference voltage and the reference number based on the temperature at which the storage device 100 operates.

According to one or more embodiments, the memory controller 120 may increase the magnitude of an erase voltage applied during an erase operation on the first memory block BLK1 in response to the number of memory cells included in the first memory block BLK1, having a threshold voltage greater than or equal to a reference voltage, exceeding a reference number.

For example, the memory controller 120 may individually control an operating voltage (for example, an erase voltage) for each memory block's operation (for example, an erase operation) based on the threshold voltage distribution of each of the plurality of memory blocks BLK1 to BLKn.

The memory controller 120 may control the operating voltage on each memory block more adaptively, compared to the case in which the operating voltage is controlled based on the number of operations (for example, erase operations) on each of the plurality of memory blocks BLK1 to BLKn.

According to one or more embodiments, the memory controller 120 may reduce the magnitude of a program voltage applied through the first wordline WL1 in response to the number of memory cells connected to the first wordline WL1, having a threshold voltage greater than or equal to a reference voltage, exceeding a reference number.

According to one or more embodiments, the memory controller 120 may increase the magnitude of a read voltage applied through the first wordline WL1 in response to the number of memory cells connected to the first wordline WL1, having a threshold voltage greater than or equal to a reference voltage, exceeding a reference number.

Referring to the above-described configurations, the memory controller 120 according to one or more embodiments may control the magnitude of an operating voltage for the operation of the memory device 110 based on the distribution of threshold voltages of the memory cells.

When the memory controller 120 controls the magnitude of the operating voltage based on the threshold voltage distribution, the memory controller 120 may control the magnitude of the operating voltage more adaptively compared to the case in which the magnitude of the operating voltage is controlled based on the number of operations (for example, erase operations).

The magnitude of the voltage required for an erase operation may increase as the time interval between consecutive program operations decreases. Accordingly, the memory controller 120 may control the magnitude of the erase voltage based on the threshold voltage distribution to perform an erase operation with a voltage corresponding to the voltage magnitude required as the time interval between consecutive program operations decrease.

The magnitude of the voltage required for a program operation may decrease as the time interval between consecutive program operations decreases. Accordingly, the memory controller 120 may control the magnitude of the program voltage based on the threshold voltage distribution to perform a program operation with a voltage corresponding to the required voltage magnitude as the time interval between consecutive program operations decreases.

For example, the memory controller 120 may control an operation on the memory device 110 using a voltage corresponding to the operating voltage required due to changes in characteristics of the memory device 110, based on the threshold voltage distribution.

The above-described configurations enable the memory system 10 (or the storage device 100) according to one or more embodiments to improve the performance of operations (for example, an erase operation, a program operation, or a read operation) on the memory device 110.

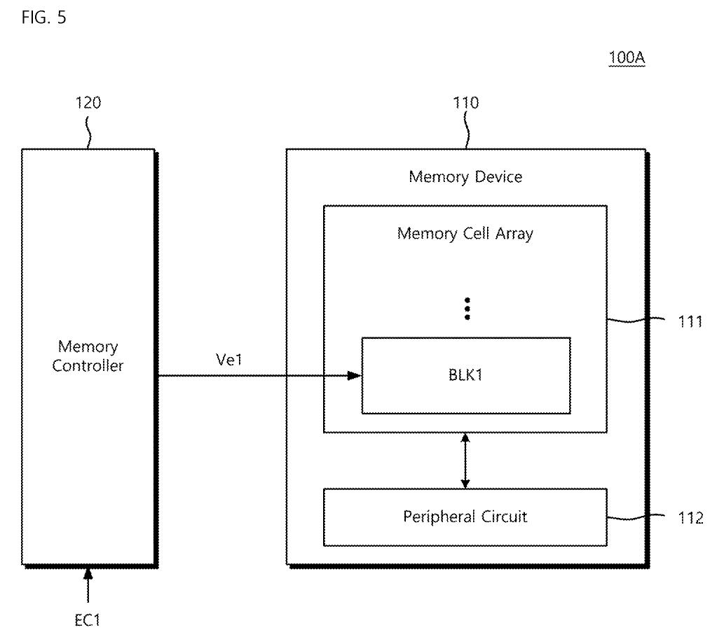

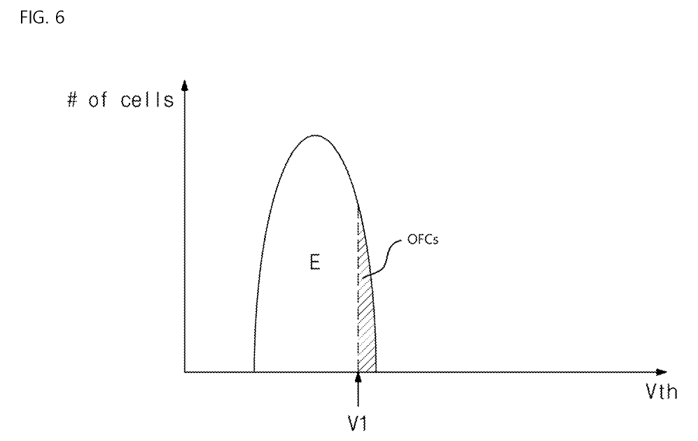

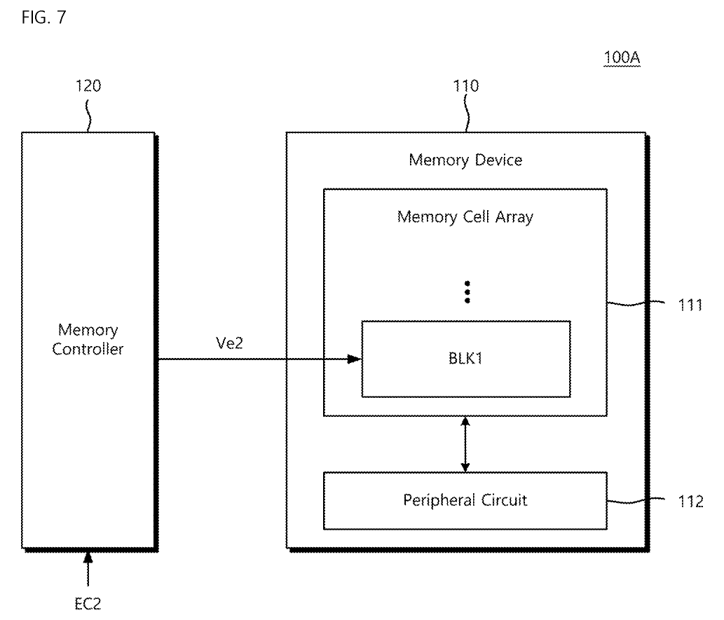

FIG. 5 is a diagram illustrating a configuration in which a memory controller according to one or more embodiments applies a first erase voltage to a first memory block. FIG. 6 is a diagram illustrating a configuration in which a memory controller according to one or more embodiments determines the number of memory cells, each having a threshold voltage greater than or equal to a first reference voltage. FIG. 7 is a diagram illustrating a configuration in which a memory controller according to one or more embodiments applies a second erase voltage to a first memory block.

Referring to FIGS. 5 and 7, a storage device 100A according to one or more embodiments may include a memory device 110 and a memory controller 120. The storage device 100A illustrated in FIGS. 5 and 7 may be understood as an example of the storage device 100 illustrated in FIG. 2. Therefore, the same or substantially the same components as described above are denoted by the same reference numerals and redundant descriptions thereof will be omitted.

Referring to FIGS. 5-7, the memory controller 120 according to one or more embodiments may control an erase voltage for an erase operation on a first memory block BLK1 based on a distribution of threshold voltages of memory cells included in the first memory block BLK1.

Referring to FIG. 5, a memory controller 120 according to one or more embodiments may perform an erase operation on a first memory block BLK1. The memory controller 120 may erase a plurality of memory cells included in the first memory block BLK1.

For example, the memory controller 120 may apply a first erase voltage Ve1 to the first memory block BLK1 in response to a first erase command EC1. The memory controller 120 may apply the first erase voltage Ve1 to a plurality of memory cells included in the first memory block BLK1 in response to a first erase command EC1.

Referring to FIGS. 5 and 6, the memory controller 120 may transition the distribution of threshold voltages of memory cells, included in the first memory block BLK1, to an erased state E in response to a first erase command EC1.

Referring to FIG. 6, the memory controller 120 according to one or more embodiments may determine the number of off-cells OFCs among memory cells in an erased state E I which a threshold voltage is greater than or equal to a first reference voltage V1. The memory controller 120 may count the number of off-cells OFCs among the memory cells in the erased state E in which a threshold voltage is greater than or equal to a first reference voltage V1. For example, the first reference voltage V1 may be a predetermined value stored in the memory device 110.

For example, the memory controller 120 may apply a first reference voltage V1 to each of the memory cells included in the first memory block BLK1. The memory controller 120 may count the number of off-cells OFCs, each having a threshold voltage is equal to or greater than the first reference voltage V1, based on the current output from each of the memory cells included in the first memory block BLK1.

The memory controller 120 may determine whether the number of off-cells OFCs among the memory cells included in the first memory block BLK1, each having a threshold voltage greater than or equal to a first reference voltage V1, exceeds a reference number. For example, the reference number may be a predetermined value stored in the memory device 110.

For example, the memory controller 120 may determine whether the number of off-cells OFCs among the memory cells in the erased state E within the first memory block BLK1, each having a threshold voltage greater than or equal to a first reference voltage V1, exceeds a reference number.

The memory controller 120 according to one or more embodiments may control the first reference voltage V1 and/or the reference number based on the temperature at which the storage device 100A operates.

In one embodiment, the memory controller 120 may increase the magnitude of the first reference voltage V1 and decrease the reference number in response to the storage device 100A operating below a pre-set threshold temperature.

In another example, the memory controller 120 may reduce the magnitude of the first reference voltage V1 and increase the reference number in response to the storage device 100A exceeding a predetermined threshold temperature.

Referring to FIGS. 6 and 7, the memory controller 120 may obtain a second erase voltage Ve2 in response to the number of off-cells OFCs exceeding a reference number.

For example, the memory controller 120 may obtain the second erase voltage Ve2 by adding a unit erase voltage to the first erase voltage Ve1 in response to the number of off-cells OFCs exceeding a reference number. A value of the unit erase voltage may be predetermined and stored in the memory device 110.

For example, the memory controller 120 may update a first voltage code corresponding to the first erase voltage Ve1 to a second voltage code corresponding to the second erase voltage Ve2 in response to the number of off-cells OFCs exceeding a reference number.

For example, after an erase operation, when the number of off-cells OFCs among the memory cells included in the first memory block BLK1, each having a threshold voltage greater than or equal to the first reference voltage V1, exceeds the reference number, the memory controller 120 may increase the erase voltage for the erase operation.

The memory controller 120 may store the value of the second erase voltage Ve2 or a second voltage code corresponding to the second erase voltage Ve2. For example, the memory controller 120 may store the value of the second erase voltage Ve2 or a second voltage code corresponding to the second erase voltage Ve2 in the memory device 110. For example, the memory controller 120 may store the value of the second erase voltage Ve2 or a second voltage code corresponding to the second erase voltage Ve2 in at least a portion of the plurality of memory blocks BLK1 to BLKn.

Referring to FIG. 7, the memory controller 120 may apply the second erase voltage Ve2 to the first memory block BLK1.

For example, the memory controller 120 may apply the second erase voltage Ve2 to the first memory block BLK1 in response to a second erase command EC2. For example, the memory controller 120 may perform an erase operation on the first memory block BLK1 using the second erase voltage Ve2 in response to a second erase command EC2. For example, the memory controller 120 may apply the stored second erase voltage Ve2 to the first memory block BLK1 in response to receiving a second erase command EC2.

For example, after updating the erase voltage based on the threshold voltage distribution of the memory cells, the memory controller 120 may perform an erase operation using the updated erase voltage (for example, the second erase voltage Ve2) in response to an erase command (for example, a second erase command EC2).

Referring to the above-described configurations, the memory controller 120 according to one or more embodiments may determine whether the number of off-cells OFCs, each having a threshold voltage greater than or equal to a reference voltage (for example, a first reference voltage V1), exceeds a reference number, after performing an erase operation on the first memory block BLK1.

The memory controller 120 may increase the erase voltage for an erase operation on the first memory block BLK1 in response to the number of off-cells OFCs exceeding a reference number.

The magnitude of the voltage required for an erase operation may increase as the time interval between consecutive program operations decreases.

Accordingly, for example, the memory controller 120 may control the magnitude of the erase voltage based on the threshold voltage distribution to increase the erase voltage by a magnitude corresponding to the required voltage magnitude as the time interval between consecutive program operations decreases.

For example, the memory controller 120 may control the erase voltage by a magnitude corresponding to the required voltage magnitude according to changes in characteristics of the memory device 110, based on the threshold voltage distribution, to perform an erase operation on the memory device 110.

The above-described configurations enable the storage device 100A according to one or more embodiments to improve the performance of operations (for example, an erase operation) on the memory device 110.

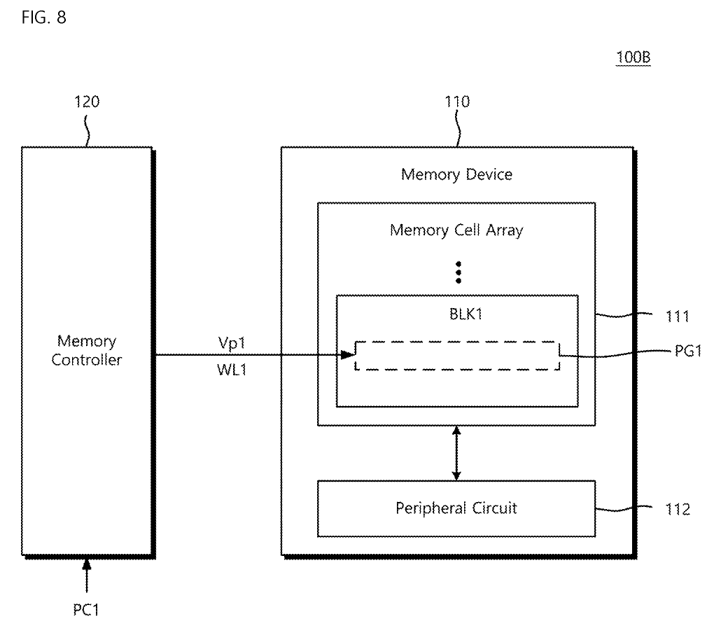

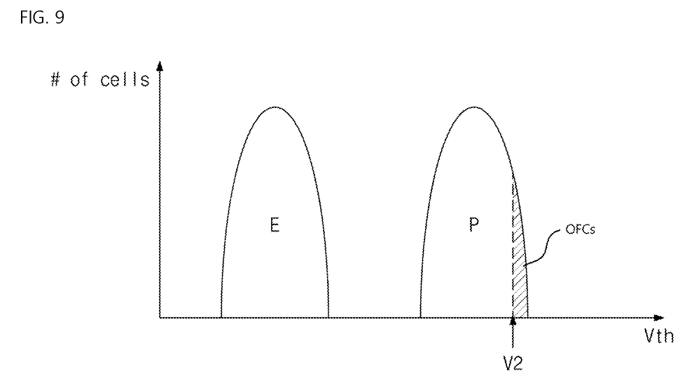

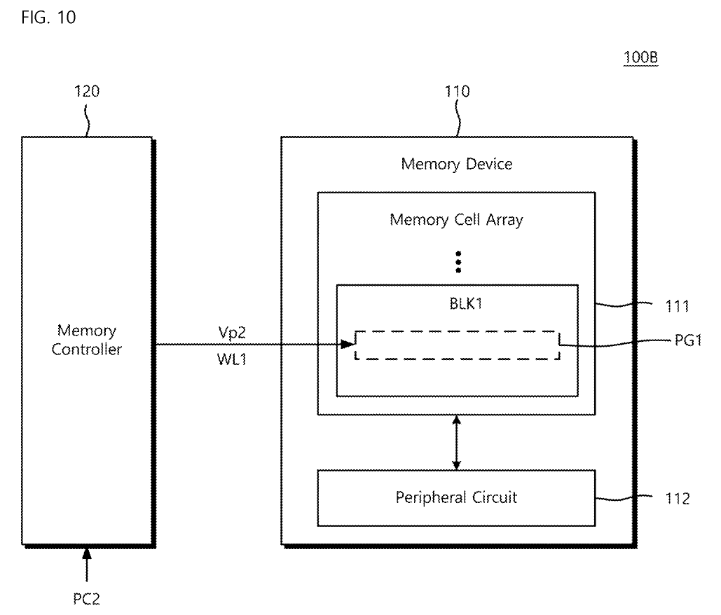

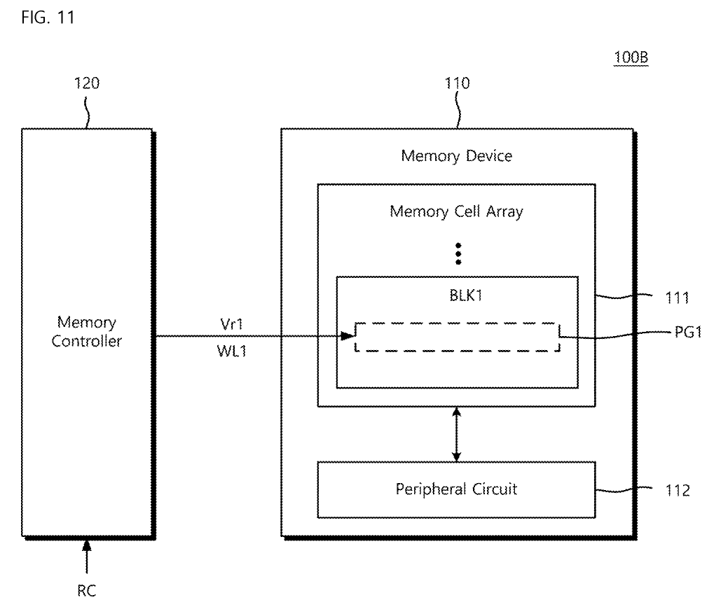

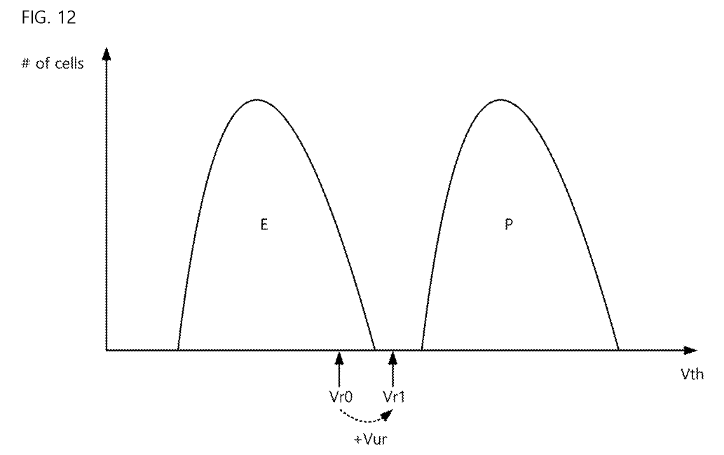

FIG. 8 is a diagram illustrating a configuration in which a memory controller according to one or more embodiments applies a first program voltage through a first wordline. FIG. 9 is a diagram illustrating a configuration in which a memory controller according to one or more embodiments determines the number of memory cells, each having a threshold voltage greater than or equal to a second reference voltage. FIG. 10 a diagram illustrating a configuration in which a memory controller according to one or more embodiments applies a second program voltage through a first wordline. FIG. 11 is a diagram illustrating a configuration in which a memory controller according to one or more embodiments applies a first read voltage through a first wordline. FIG. 12 is a diagram illustrating a configuration in which a memory controller according to one or more embodiments generates a first read voltage from a pre-read voltage.

Referring to FIGS. 8, 10, and 11, a storage device 100B according to one or more embodiments may include a memory device 110 and a memory controller 120. The storage device 100B illustrated in FIGS. 8, 10, and 11 may be understood as an example of the storage device 100 illustrated in FIG. 2. Therefore, the same or substantially the same components as described above are denoted by the same reference numerals and redundant descriptions thereof will be omitted.

Referring to FIGS. 8-10, the memory controller 120 according to one or more embodiments may control a program voltage for a program operation on memory cells included in a first page PG1, based on a threshold voltage distribution of the memory cells included in the first page PG1.

Referring to FIG. 8, the memory controller 120 may perform a program operation on the memory cells included in the first page PG1. The memory controller 120 may program data into memory cells included in the first page PG1. The first page PG1 may include memory cells connected to a first wordline WL1, among memory cells included in a first memory block BLK1.

For example, the memory controller 120 may apply a first program voltage Vp1 through a first wordline WL1 in response to a first program command PC1. The first wordline WL1 may be understood to be connected to the first page PG1. Accordingly, the memory controller 120 may apply the first program voltage Vp1 to memory cells, included in the first page PG1, through the first wordline WL1 in response to a first program command PC1.

Referring to FIGS. 8 and 9, the memory controller 120 may transition a threshold voltage distribution of at least a portion of the memory cells included in the first page PG1 to a program state P in response to a first program command PC1.

For example, a program operation on the first page PG1 illustrated in FIG. 8 may be understood as an operation performed after the erase operation on the first memory block BLK1 illustrated in FIG. 5.

For example, a program operation on the first page PG1 illustrated in FIG. 8 may be understood as a first program operation performed after the erase operation on the first memory block BLK1 illustrated in FIG. 5.

The memory controller 120 according to one or more embodiments may determine the number of off-cells, each having a threshold voltage greater than or equal to a second reference voltage V2 OFCs, among the memory cells included in the first page PG1.

For example, the memory controller 120 may count the number of off-cells OFCs, each having a threshold voltage greater than or equal to a second reference voltage V2, among the memory cells in the program state P.

The memory controller 120 may determine whether the number of off-cells OFCs, each having a threshold voltage greater than or equal to a second reference voltage V2, among the memory cells included in the first page PG1 exceeds a reference number. For example, the reference number may be a predetermined value stored in the memory device 110.

For example, the memory controller 120 may determine whether the number of off-cells OFCs each having a threshold voltage greater than or equal to a second reference voltage V2, among the memory cells in the program state P within the first page PG1, exceeds the reference number.

Referring to FIGS. 9 and 10, the memory controller 120 may obtain a second program voltage Vp2 in response to the number of off-cells OFCs exceeding a reference number.

For example, the memory controller 120 may obtain the second program voltage Vp2 by subtracting a unit program voltage from the first program voltage Vp1 in response to the number of off-cells OFCs exceeding a reference number. The value of the unit program voltage may be predetermined and stored in the memory device 110.

For example, the memory controller 120 may update a first voltage code corresponding to the first program voltage Vp1 to a second voltage code corresponding to the second program voltage Vp2 in response to the number of off-cells OFCs exceeding a reference number.

For example, after a program operation, when the number of off-cells OFCs among the memory cells included in the first page PG1, each having a threshold voltage greater than or equal to the second reference voltage V2, exceeds the reference number, the memory controller 120 may decrease the program voltage

The memory controller 120 may store the value of the second program voltage Vp2 or a second voltage code corresponding to the second program voltage Vp2. For example, the memory controller 120 may store the value of the second program voltage Vp2 or a second voltage code corresponding to the second program voltage Vp2 in the memory device 110. For example, the memory controller 120 may store the value of the second program voltage Vp2 or a second voltage code corresponding to the second program voltage Vp2 in at least a portion of the plurality of memory blocks BLK1 to BLKn.

Referring to FIG. 10, the memory controller 120 may apply the second program voltage Vp2 through the first wordline WL1.

For example, the memory controller 120 may apply the second program voltage Vp2 to the first page PG1 through the first wordline WL1 in response to a second program command PC2. For example, the second program voltage Vp2 may have a value corresponding to a second voltage code stored in the memory device 110.

For example, the memory controller 120 may perform a program operation on the memory cells included in the first page PG1 using the second program voltage Vp2 in response to a second program command PC2. For example, the memory controller 120 may apply a prestored second program voltage Vp2 through the first wordline WL1 in response to receiving a second program command PC2.

For example, after updating the program voltage based on the threshold voltage distribution of the memory cells, the memory controller 120 may perform a program operation using the updated program voltage (for example, the second program voltage Vp2) in response to a program command (for example, a second program command PC2).

Referring to the above-described configurations, the memory controller 120 may determine whether the number of off-cells OFCs, each having a threshold voltage greater than or equal to a reference voltage (for example, a second reference voltage V2), exceeds a reference number after performing a program operation on the first page PG1.

The memory controller 120 may reduce the program voltage for a program operation on the memory cells included in the first page PG1 in response to the number of off-cells OFCs exceeding the reference number.

For example, the memory controller 120 may control the program voltage by a magnitude corresponding to the required voltage magnitude according to changes in characteristics of the memory device 110, based on the threshold voltage distribution, to perform a program operation on the memory device 110.

Referring to FIGS. 8, 9, 11, and 12, the memory controller 120 according to one or more embodiments may control a read voltage for a read operation on memory cells included in a first page PG1, based on the threshold voltage distribution of the memory cells included in the first page PG1.

Referring to FIGS. 11 and 12, the memory controller 120 may perform a read operation on memory cells included in a first page PG1. The memory controller 120 may read data stored in memory cells included in the first page PG1.

For example, the memory controller 120 may apply a first read voltage Vr1 through the first wordline WL1 in response to a read command RC for memory cells included in the first page PG1.

The first wordline WL1 may be understood to be connected to the first page PG1. Accordingly, the memory controller 120 may apply the first read voltage Vr1 to memory cells, included in the first page PG1, through the first wordline WL1 in response to a read command RC.

The read operation on the first page PG1 illustrated in FIG. 11 may be understood as an operation performed after the operation of updating the voltage code based on the number of off-cells OFCs illustrated in FIG. 9. For example, the read operation on the first page PG1 illustrated in FIG. 11 may be understood as an operation performed after the operation of storing the second voltage code based on the number of off-cells OFCs illustrated in FIG. 9.

Accordingly, the first read voltage Vr1 according to one or more embodiments may have a value corresponding to a pre-stored second voltage code. The second voltage code may be understood as a code stored in response to the number of off-cells OFCs exceeding the reference number.

Referring to FIG. 12, the first read voltage Vr1 may have a value obtained by adding a unit read voltage Vur to a pre-read voltage Vr0. The pre-read voltage Vr0 may be understood as a voltage applied through the first wordline WL1 in a read operation performed before the program operation illustrated in FIG. 8. The unit read voltage Vur may be predetermined and stored in the memory device 110.

For example, the memory controller 120 may increase the read voltage for a read operation on the first page PG1 in response to the number of off-cells OFCs, among the memory cells included in the first page PG1, exceeding a reference number.

Referring to the above-described configurations, the memory controller 120 may determine whether the number of off-cells OFCs whose threshold voltage greater than or equal to a reference voltage (for example, a second reference voltage V2) exceeds a reference number after performing a program operation on the first page PG1.

The memory controller 120 may update a voltage code corresponding to an operating voltage for an operation on memory cells included in the first page PG1 in response to the number of off-cells OFCs exceeding a reference number.

The memory controller 120 may perform an operation on memory cells included in the first page PG1 using an operating voltage corresponding to the updated voltage code in response to an operation command for memory cells included in the first page PG1.

For example, the memory controller 120 may perform a program operation on memory cells included in the first page PG1 using the second program voltage Vp2 corresponding to a second voltage code in response to a second program command PC2.

The magnitude of the voltage required for a program operation may decrease as the time interval between consecutive program operations decreases.

Accordingly, the memory controller 120 may by control the magnitude of the program voltage based on the threshold voltage distribution to decrease the program voltage by a magnitude corresponding to the required voltage magnitude as the time interval between consecutive program operations decreases.

In another example, the memory controller 120 may perform a read operation on memory cells included in the first page PG1 using the first read voltage Vr1 corresponding to a second voltage code.

For example, the memory controller 120 may control the read voltage by a magnitude corresponding to the required voltage magnitude according to changes in characteristics of the memory device 110, based on the threshold voltage distribution, to perform a read operation on the memory device 110.

The above-described configurations enable the storage device 100B according to one or more embodiments to improve the performance of operations (for example, a program operation and a read operation) on the memory device 110.

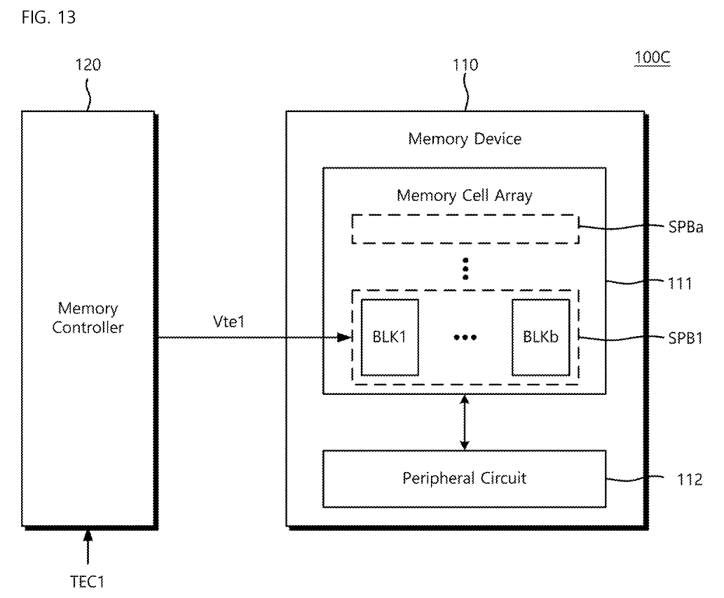

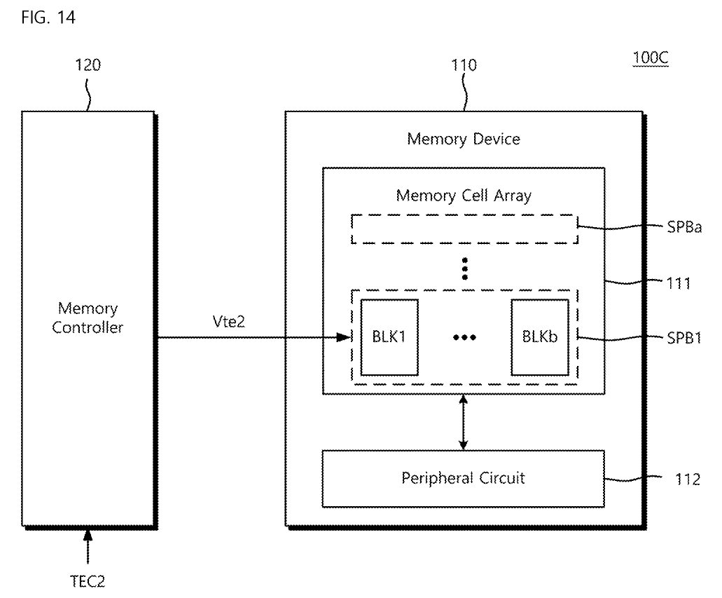

FIG. 13 a diagram illustrating a configuration in which a memory controller according to one or more embodiments applies a first batch erase voltage to a first super block. FIG. 14 is a diagram illustrating a configuration in which a memory controller according to one or more embodiments applies a second batch erase voltage to a first super block.

Referring to FIGS. 13 and 14, a storage device 100C according to one or more embodiments may include a memory device 110 and a memory controller 120. The storage device 100C illustrated in FIGS. 13 and 14 may be understood as an example of the storage device 100 illustrated in FIG. 2. Therefore, the same or substantially the same components as described above are denoted by the same reference numerals and redundant descriptions thereof will be omitted.

Referring to FIGS. 13 and 14, the memory controller 120 according to one or more embodiments may control a batch erase voltage for a batch erase operation on a first super block SPB1 based on the threshold voltage distribution of memory cells included in the first super block SPB1.

According to one or more embodiments, the memory cell array 111 may include a plurality of super blocks SPB1 to SPBa (where 'a' is an arbitrary integer greater than or equal to 2). Each of the plurality of super blocks SPB1 to SPBa may include a plurality of memory blocks. For example, the first super block SPB1 may include a plurality of memory blocks BLK1 to BLKb (where 'b' is an arbitrary integer greater than or equal to 2). Each of the super blocks excluding the first super block SPB1, among the plurality of super blocks SPB1 to SPBa, may include 'b' memory blocks.

Each of the plurality of super blocks SPB1 to SPBa may be a unit of a batch erase operation controlled by the memory controller 120. For example, the memory controller 120 may control a batch erase operation on each of the plurality of super blocks SPB1 to SPBa.

Referring to FIG. 13, the memory controller 120 according to one or more embodiments may perform a batch erase operation on a first super block SPB1. The memory controller 120 may erase a plurality of memory cells included in the first super block SPB1.

For example, the memory controller 120 may apply a first batch erase voltage Vte1 to the first super block SPB1 in response to a first batch erase command TEC1. The memory controller 120 may apply a first batch erase voltage Vte1 to each of the plurality of memory blocks BLK1 to BLKb included in the first super block SPB1 in response to a first batch erase command TEC1.

For example, the memory controller 120 may transition the threshold voltage distribution of memory cells included in the first super block SPB1 to an erased state in response to a first batch erase command TEC1.

The memory controller 120 according to one or more embodiments may determine the number of off-cells, each having a threshold voltage greater than or equal to a first reference voltage, in each of the plurality of memory blocks BLK1 to BLKb.

The memory controller 120 may determine whether the number of memory blocks, among the plurality of memory blocks BLK1 to BLKb in which the number of off-cells exceeds a reference number, is greater than or equal to a first number. Each of the reference number and the first number may be a predetermined value stored in the memory device 110.

In one example, the value of the first number may be "1." For example, the memory controller 120 may determine whether the number of memory blocks, among the plurality of memory blocks BLK1 to BLKb in which the number of off-cells exceeds a reference number, is equal to or greater than 1.

In another example, the value of the first number may be half of 'b.' For example, the memory controller 120 may determine whether the number of memory blocks, among the plurality of memory blocks BLK1 to BLKb in which the number of off-cells exceeds a reference number, is greater than or equal to half.

For example, the memory controller 120 may determine whether the number of memory blocks among the plurality of memory blocks BLK1 to BLKb, in which the number of off-cells each having a threshold voltage greater than or equal to the first reference voltage exceeds a reference number, exceeds a first number.

Referring to FIGS. 13 and 14, the memory controller 120 may obtain a second batch erase voltage Vte2 in response to the number of memory blocks, in which the number of off-cells exceeds a reference number, being greater or equal to than the first number.

For example, the memory controller 120 may obtain a second batch erase voltage Vte2 by adding a unit erase voltage to a first batch erase voltage Vte1 in response to the number of memory blocks, in which the number of off-cells exceeds a reference number, being greater than or equal to a first number. A value of the unit erase voltage may be predetermined and stored in the memory device 110.

For example, the memory controller 120 may update a first voltage code corresponding to a first batch erase voltage Vte1 to a second voltage code corresponding to a second batch erase voltage Vte2 in response to the number of memory blocks, in which the number of off-cells exceeds a reference number, being greater than or equal to the first number.

For example, after an erase operation, when the number of memory blocks included in the first super block SPB1 in which the number of off-cells exceeds a reference number is greater than or equal to a first number, the memory controller 120 may increase the batch erase voltage.

The memory controller 120 may store the value of the second batch erase voltage Vte2 or a second voltage code corresponding to the second batch erase voltage Vte2. For example, the memory controller 120 may store the value of the second batch erase voltage Vte2 or a second voltage code corresponding to the second batch erase voltage Vte2 in the memory device 110. For example, the memory controller 120 may store the value of the second batch erase voltage Vte2 or a second voltage code corresponding to the second batch erase voltage Vte2 in at least a portion of the plurality of memory blocks BLK1 to BLKn.

Referring to FIG. 14, the memory controller 120 may apply a second batch erase voltage Vte2 to the first super block SPB1.

For example, the memory controller 120 may apply a second batch erase voltage Vte2 to each of the plurality of memory blocks BLK1 to BLKb included in the first super block SPB1 in response to a second batch erase command TEC2. For example, the memory controller 120 may perform an erase operation on the first super block SPB1 using a second batch erase voltage Vte2 in response to a second batch erase command TEC2. For example, the memory controller 120 may apply a pre-stored second batch erase voltage Vte2 to the first super block SPB1 in response to receiving a second batch erase command TEC2.

For example, after updating the erase voltage based on the threshold voltage distribution of the memory cells, the memory controller 120 may perform a batch erase operation using the updated batch erase voltage (for example, the second batch erase voltage Vte2) in response to a batch erase command (for example, a second batch erase command TEC2).

Referring to the above-described configurations, the memory controller 120 may determine whether the number of memory blocks, in which the number of off-cells exceeds a reference number, is greater than or equal to a first number, after performing an erase operation on the first super block SPB1.

The memory controller 120 may increase the batch erase voltage for a batch erase operation on the first super block SPB1 in response to the number of memory blocks in which the number of off-cells exceeds a reference number being greater than or equal to a first number.

The magnitude of the voltage required for a batch erase operation may increase as the time interval between consecutive program operations decreases.

Accordingly, for example, the memory controller 120 may control the magnitude of the batch erase voltage based on the threshold voltage distribution to increase the batch erase voltage by a magnitude corresponding to the voltage magnitude required as the time interval between consecutive program operations decreases.

For example, the memory controller 120 may control the batch erase voltage by a magnitude corresponding to the required voltage magnitude according to changes in characteristics of the memory device 110, based on the threshold voltage distribution, to perform a batch erase operation on the memory device 110.

Referring to the above-described configurations, the memory controller 120 according to one or more embodiments may control a batch erase voltage for a first super block SPB1 based on the threshold voltage distribution of the plurality of memory blocks BLK1 to BLKb.

Accordingly, the memory controller 120 may control the batch erase voltage within a relatively short time compared to the case in which the erase voltage for each of the plurality of memory blocks BLK1 to BLKb is individually controlled.

The above-described configurations enable the storage device 100C according to one or more embodiments to improve the performance of operations (for example, a batch erase operation) on the memory device 110.

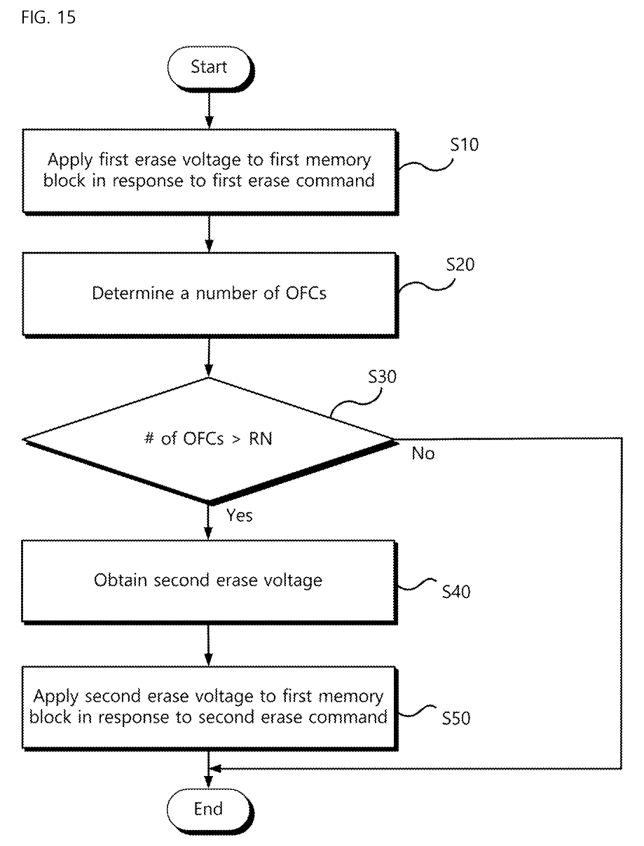

FIG. 15 is a flowchart illustrating a method, performed by a storage device according to one or more embodiments, of controlling the magnitude of an erase voltage based on threshold voltages of memory cells. FIG. 15 will be described with reference to FIGS. 5, 6, and 7.

Referring to FIG. 15, the memory controller 120 (or the storage device 100) according to one or more embodiments may control an erase voltage for an erase operation on a first memory block BLK1 based on the threshold voltage distribution of memory cells included in the first memory block BLK1.

In operation S10, the memory controller 120 according to one or more embodiments may apply the first erase voltage Ve1 to a first memory block BLK1 in response to a first erase command EC1.

For example, the memory controller 120 may apply the first erase voltage Ve1 to a plurality of memory cells included in the first memory block BLK1 in response to a first erase command EC1.

For example, the memory controller 120 according to one or more embodiments may perform an erase operation on the first memory block BLK1 in response to the first erase command EC1.

The memory controller 120 may transition or drive the threshold voltage distribution of memory cells included in the first memory block BLK1 to an erased state E in response to the first erase command EC1.

In operation S20, the memory controller 120 according to one or more embodiments may determine the number of off-cells OFCs.

For example, the memory controller 120 may determine the number of off-cells OFCs, each having a threshold voltage greater than or equal to a reference voltage (for example, the first reference voltage V1 of FIG. 6), among the memory cells in the erased state E.

For example, the memory controller 120 may count the number of off-cells OFCs, each having a threshold voltage greater than or equal to the reference voltage, among the memory cells in the erased state E.

In operation S30, the memory controller 120 according to one or more embodiments may determine whether the number of off-cells OFCs exceeds a reference number RN. For example, the reference number RN may be a predetermined value stored in the memory device 110.

For example, the memory controller 120 may determine whether the number of off-cells OFCs, each having a threshold voltage greater than or equal to the reference voltage, exceeding the reference number RN, among the memory cells in the erased state E within the first memory block BLK1.

The memory controller 120 according to one or more embodiments may control the reference voltage and/or the reference number RN based on the temperature at which the storage device 100 operates.

In one example, the memory controller 120 may increase the magnitude of the reference voltage and decrease the reference number RN in response to the storage device 100 being lower than or equal to a predetermined threshold temperature.

In another example, the memory controller 120 may reduce the magnitude of the reference voltage and increase the reference number RN in response to the storage device 100 exceeding a predetermined threshold temperature.

In operation S40, the memory controller 120 according to one or more embodiments may obtain the second erase voltage Ve2 in response to the number of off-cells OFCs exceeding the reference number RN.

For example, the memory controller 120 may obtain the second erase voltage Ve2 by adding a unit erase voltage to the first erase voltage Ve1 in response to the number of off-cells OFCs exceeding the reference number RN. The value of the unit erase voltage may be predetermined and stored in the memory device 110.

For example, the memory controller 120 may update a first voltage code corresponding to the first erase voltage Ve1 to a second voltage code corresponding to the second erase voltage Ve2 in response to the number of off-cells OFCs exceeding the reference number RN.

For example, after an erase operation, when the number of off-cells OFCs, among the memory cells included in the first memory block BLK1, each having a threshold voltage greater than or equal to the reference voltage, exceeds the reference number RN, the memory controller 120 may increase an erase voltage for an erase operation.

The memory controller 120 may store a value of the second erase voltage Ve2 or the second voltage code corresponding to the second erase voltage Ve2. For example, the memory controller 120 may store the value of the second erase voltage Ve2 or the second voltage code corresponding to the second erase voltage Ve2 in the memory device 110. For example, the memory controller 120 may store the value of the second erase voltage Ve2 or the second voltage code corresponding to the second erase voltage Ve2 in at least a portion of the plurality of memory blocks BLK1 to BLKn.

In operation S50, the memory controller 120 according to one or more embodiments may apply the second erase voltage Ve2 to the first memory block BLK1.

For example, the memory controller 120 may apply the second erase voltage Ve2 to the first memory block BLK1 in response to a second erase command EC2. For example, the memory controller 120 may perform an erase operation on the first memory block BLK1 using the second erase voltage Ve2 in response to the second erase command EC2. For example, the memory controller 120 may apply the stored second erase voltage Ve2 to the first memory block BLK1 in response to receiving the second erase command EC2.

For example, after updating the erase voltage based on the threshold voltage distribution of the memory cells, the memory controller 120 may perform an erase operation using the updated erase voltage (for example, the second erase voltage Ve2) in response to receiving an erase command (for example, a second erase command EC2).

Referring to the above-described configurations, the memory controller 120 may determine whether the number of off-cells OFCs, each having a threshold voltage greater than or equal to a reference voltage, exceeds a reference number RN after performing an erase operation on the first memory block BLK1.

The memory controller 120 may increase the erase voltage for an erase operation on the first memory block BLK1 in response to the number of off-cells OFCs exceeding the reference number RN.

The magnitude of the voltage required for an erase operation may increase as the time interval between consecutive program operations decreases.

Accordingly, for example, the memory controller 120 may control the magnitude of the erase voltage based on the threshold voltage distribution to increase the erase voltage by a magnitude corresponding to the voltage magnitude required as the time interval between consecutive program operations decreases.

For example, the memory controller 120 may control the erase voltage by a magnitude corresponding to the required voltage magnitude according to changes in characteristics of the memory device 110, based on the threshold voltage distribution, to perform an erase operation on the memory device 110.

The above-described configurations enables the storage device 100 according to one or more embodiments to improve the performance of operations (for example, an erase operation) on the memory device 110.

According to one or more embodiments, the memory controller 120 may determine the number of off-cells OFCs in response to performing an erase operation on the first memory block BLK1 a predetermined number of times using the second erase voltage Ve2.

For example, after performing an erase operation on the first memory block BLK1 a predetermined number of times using the second erase voltage Ve2, the memory controller 120 may determine the number of off-cells OFCs whose threshold voltage greater than or equal to a reference voltage in response to an erase command. For example, once the erase voltage of the erase operation has been updated to the second erase voltage Ve2, after a predetermined number of performing the erase operation using the second erase voltage Ve2, the memory controller 120 may perform a step corresponding to the step S20 to determine whether to perform an update of the erase voltage based on the number of off-cells.

A third erase voltage may be obtained by adding a unit erase voltage to the second erase voltage Ve2 in response to the number of off-cells OFCs exceeding a reference number RN.

For example, the memory controller 120 may determine whether the number of off-cells OFCs exceeds a reference number RN according to a designated operation cycle. The memory controller 120 may increase the erase voltage when the number of off-cells OFCs exceeds a reference number RN.

Referring to the above-described configurations, the memory controller 120 according to one or more embodiments may determine whether the number of off-cells OFCs exceeds a reference number RN each time a predetermined number of erase operations are performed. The memory controller 120 may increase the erase voltage when the number of off-cells OFCs exceeds a reference number RN.

Accordingly, the memory controller 120 may control the operating voltage a relatively fewer number of times compared to the case in which when controlling the operating voltage is controlled based on whether the number of off-cells OFCs exceeds a reference number RN each time an erase operation is performed.

The above-described configurations enables the storage device 100 according to one or more embodiments to reduce the time and power consumed to control the operating voltage.

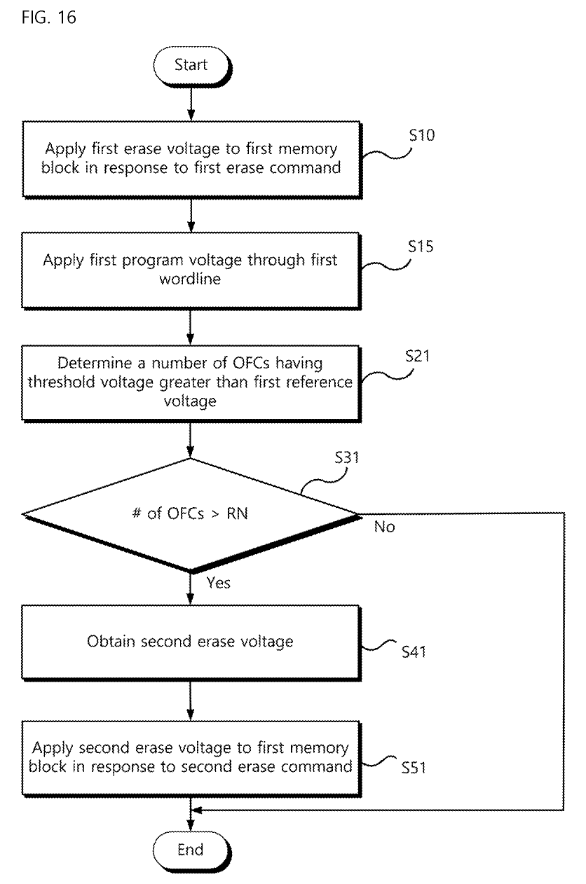

FIG. 16 is a flowchart illustrating a method, performed by a storage controller according to one or more embodiments, of controlling the magnitude of an erase voltage based on threshold voltages of memory cells after performing a program operation. FIG. 16 will be described with reference to FIGS. 8, 9, and 10.

Referring to FIG. 16, the memory controller 120 (or the storage device 100) according to one or more embodiments may control an erase voltage for an erase operation on a first memory block BLK1 based on the threshold voltage distribution of memory cells included in the first memory block BLK1.

In operation S10, the memory controller 120 according to one or more embodiments may apply the first erase voltage Ve1 to the first memory block BLK1 in response to a first erase command EC1.

For example, the memory controller 120 may apply the first erase voltage Ve1 to a plurality of memory cells included in the first memory block BLK1 in response to the first erase command EC1.

For example, the memory controller 120 according to one or more embodiments may perform an erase operation on the first memory block BLK1 in response to the first erase command EC1.

In operation S15, the memory controller 120 according to one or more embodiments may apply the first program voltage Vp1 through a first wordline WL1.

For example, the memory controller 120 may apply the first program voltage Vp1 through the first wordline WL1 in response to a first program command PC1 for memory cells included in a first page PG1. The first wordline WL1 may be understood to be connected to the first page PG1. Accordingly, the memory controller 120 may apply the first program voltage Vp1 to the memory cells included in the first page PG1 through the first wordline WL1 in response to the first program command PC1.

For example, the memory controller 120 may transition the threshold voltage distribution of at least a portion of the memory cells included in the first page PG1 to a program state P in response to the first program command PC1 for the memory cells included in the first page PG1.

In operation S21, the memory controller 120 according to one or more embodiments may determine the number of off-cells OFCs, each having a threshold voltage greater than or equal to a first reference voltage V1.

For example, the memory controller 120 may determine the number of off-cells OFCs each having a threshold voltage greater than or equal to a first reference voltage V1, among the memory cells in the program state P. For example, the memory controller 120 may count the number of off-cells OFCs each having a threshold voltage greater than or equal to a first reference voltage V1, among the memory cells in the program state P (e.g., the memory cells included in the first page PG1).

In operation S31, the memory controller 120 according to one or more embodiments may determine whether the number of off-cells OFCs exceeds a reference number RN. For example, the reference number RN may be a predetermined value stored in the memory device 110.

For example, the memory controller 120 may determine whether the number of off-cells OFCs each having a threshold voltage greater than or equal to a first reference voltage V1, among the memory cells in the program state P within the first memory block BLK1, exceeds a reference number RN.

In operation S41, the memory controller 120 according to one or more embodiments may obtain the second erase voltage Ve2 in response to the number of off-cells OFCs exceeding a reference number RN.

For example, the memory controller 120 may obtain the second erase voltage Ve2 by adding a unit erase voltage to the first erase voltage Ve1 in response to the number of off-cells OFCs, each having a threshold voltage greater than or equal to the first reference voltage V1, exceeding the reference number RN. The value of the unit erase voltage may be predetermined and stored in the memory device 110.

For example, the memory controller 120 may update a first voltage code corresponding to the first erase voltage Ve1 to a second voltage code corresponding to the second erase voltage Ve2 in response to the number of off-cells OFCs exceeding a reference number RN.

For example, after an erase operation, when the number of off-cells OFCs each having a threshold voltage greater than or equal to a first reference voltage V1, among the memory cells included in the first memory block BLK1, exceeds a reference number RN, the memory controller 120 may increase the erase voltage for the erase operation.

The memory controller 120 may store the value of the second erase voltage Ve2 or the second voltage code corresponding to the second erase voltage Ve2. For example, the memory controller 120 may store the value of the second erase voltage Ve2 or the second voltage code corresponding to the second erase voltage Ve2 in the memory device 110.

In operation S51, the memory controller 120 according to one or more embodiments may apply the second erase voltage Ve2 to the first memory block BLK1.

For example, the memory controller 120 may apply the second erase voltage Ve2 to the first memory block BLK1 in response to a second erase command EC2. For example, the memory controller 120 may perform an erase operation on the first memory block BLK1 using the second erase voltage Ve2 in response to the second erase command EC2. For example, the memory controller 120 may apply the stored second erase voltage Ve2 to the first memory block BLK1 in response to receiving the second erase command EC2.

For example, after updating the erase voltage based on the threshold voltage distribution of the memory cells, the memory controller 120 may perform an erase operation using the updated erase voltage (for example, the second erase voltage Ve2) in response to an erase command (for example, the second erase command EC2).

Referring to the above-described configurations, the memory controller 120 may determine whether the number of off-cells OFCs each having a threshold voltage greater than or equal to the first reference voltage V1, among the memory cells in the program state P, exceeds the reference number RN after applying a program voltage through the first wordline WL1.

The memory controller 120 may increase the erase voltage for an erase operation on the first memory block BLK1 in response to the number of off-cells OFCs exceeding the reference number RN among the memory cells in the program state P.

The memory controller 120 may perform an erase operation using an increased erase voltage in response to an erase command for the first memory block BLK1.

The magnitude of the voltage required for an erase operation may increase as the time interval between consecutive program operations decreases.

Accordingly, the memory controller 120 may control the magnitude of the erase voltage based on the threshold voltage distribution to increase the erase voltage by a magnitude corresponding to the required voltage magnitude as the time interval between consecutive program operations decreases.

For example, the memory controller 120 may control the erase voltage by a magnitude corresponding to the required voltage magnitude according to changes in characteristics of the memory device 110, based on the threshold voltage distribution, to perform an erase operation on the memory device 110.

The above-described configurations enable the storage device 100 according to one or more embodiments to improve the performance of operations (for example, an erase operation) on the memory device 110.

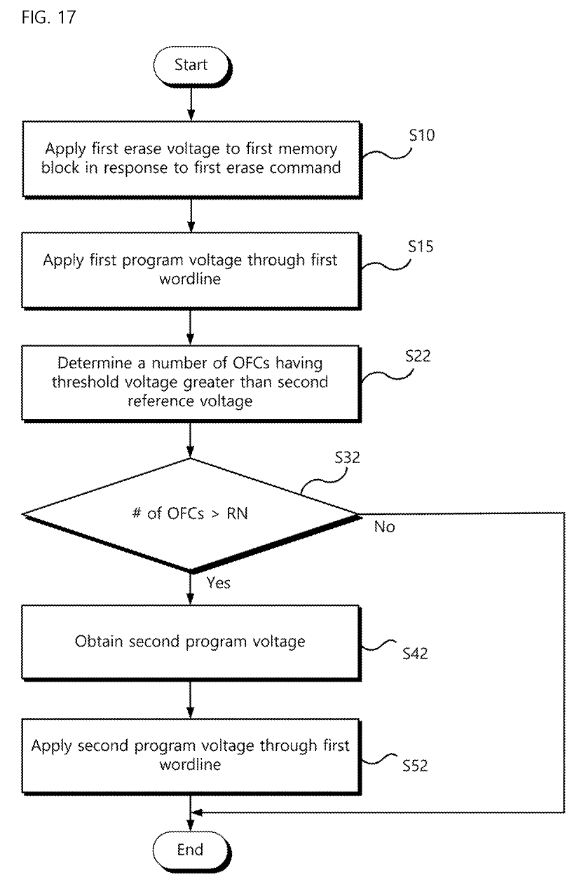

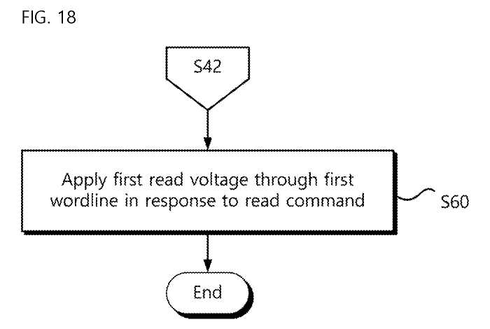

FIG. 17 is a flowchart illustrating a method, performed by a storage device according to one more embodiments, of controlling the magnitude of a program voltage based on threshold voltages of memory cells after performing a program operation. FIG. 18 is a flowchart illustrating a method, performed by a storage device according to one or more embodiments, of controlling the magnitude of a read voltage based on threshold voltages of memory cells. FIGS. 17 and 18 will be described with reference to FIGS. 10 and 11.

Referring to FIG. 17, the memory controller 120 (or the storage device 100) according to one or more embodiments may control a program voltage for a program operation on a first page PG1 based on the threshold voltage distribution of memory cells included in the first page PG1.

In operation S10, the memory controller 120 according to one or more embodiments may apply the first erase voltage Ve1 to a first memory block BLK1 in response to a first erase command EC1.

For example, the memory controller 120 may apply the first erase voltage Ve1 to a plurality of memory cells included in the first memory block BLK1 in response to the first erase command EC1.

For example, the memory controller 120 according to one or more embodiments may perform an erase operation on the first memory block BLK1 in response to the first erase command EC1.

In operation S15, the memory controller 120 according to one or more embodiments may apply the first program voltage Vp1 through a first wordline WL1.

For example, the memory controller 120 may apply the first program voltage Vp1 through the first wordline WL1 in response to a first program command PC1 for memory cells included in a first page PG1. The first wordline WL1 may be understood to be connected to the first page PG1. Accordingly, the memory controller 120 may apply the first program voltage Vp1 to memory cells included in the first page PG1 through the first wordline WL1 in response to the first program command PC1.

For example, the memory controller 120 may transition the threshold voltage distribution of at least a portion of the memory cells included in the first page PG1 to a program state P in response to the first program command PC1 for memory cells included in the first page PG1.

In operation S22, the memory controller 120 according to one or more embodiments may determine the number of off-cells OFCs, each having a threshold voltage greater than or equal to a second reference voltage V2.

For example, the memory controller 120 may determine the number of off-cells OFCs each having a threshold voltage greater than or equal to the second reference voltage V2, among the memory cells included in the first page PG1. For example, the memory controller 120 may count the number of off-cells OFCs each having a threshold voltage greater than or equal to the second reference voltage V2, among the memory cells in the program state P within the first page PG1.

In operation S32, the memory controller 120 according to one or more embodiments may determine whether the number of off-cells OFCs exceeds a reference number RN among the memory cells in the program state P within the first page PG1. For example, the reference number RN may be a predetermined value stored in the memory device 110.

For example, the memory controller 120 may determine whether the number of off-cells OFCs each having a threshold voltage greater than or equal to a second reference voltage V2, among the memory cells in the program state P within the first memory block BLK1, exceeds a reference number RN.

In operation S42, the memory controller 120 according to one or more embodiments may obtain the second program voltage Vp2 in response to the number of off-cells OFCs exceeding the reference number RN.

For example, the memory controller 120 may obtain the second program voltage Vp2 by subtracting a unit program voltage from the first program voltage Vp1 in response to the number of off-cells OFCs exceeding the reference number RN among the memory cells in the program state P. A value of the unit program voltage may be predetermined and stored in the memory device 110.

For example, the memory controller 120 may update a first voltage code corresponding to the first program voltage Vp1 to a second voltage code corresponding to the second program voltage Vp2 in response to the number of off-cells OFCs exceeding the reference number RN among the memory cells in the program state P.

For example, after a program operation, when the number of off-cells OFCs each having a threshold voltage greater than or equal to the second reference voltage V2, among the memory cells included in the first page PG1, exceeds the reference number RN, the memory controller 120 may decrease the program voltage.

The memory controller 120 may store the value of the second program voltage Vp2 or the second voltage code corresponding to the second program voltage Vp2. For example, the memory controller 120 may store the value of the second program voltage Vp2 or the second voltage code corresponding to the second program voltage Vp2 in the memory device 110.

In operation S52, the memory controller 120 according to one or more embodiments may apply the second program voltage Vp2 through the first wordline WL1 to the first page PG1.

For example, the memory controller 120 may apply the second program voltage Vp2 to the first page PG1 through the first wordline WL1 in response to a second program command PC2. For example, the memory controller 120 may perform a program operation on the memory cells included in the first page PG1 using the second program voltage Vp2 in response to the second program command PC2. For example, the memory controller 120 may apply the stored second program voltage Vp2 through the first wordline WL1 in response to receiving the second program command PC2.

For example, after updating the program voltage based on the threshold voltage distribution of the memory cells, the memory controller 120 may perform a program operation using the updated program voltage (for example, the second program voltage Vp2) in response to an erase command (for example, a second program command PC2).

Referring to the above-described configurations, the memory controller 120 may determine whether the number of off-cells OFCs each having a threshold voltage greater than or equal to the second reference voltage V2, among the memory cells in the program state P, exceeds the reference number RN after applying the program voltage through the first wordline WL1. The memory controller 120 may decrease the program voltage in response to the number of off-cells OFCs exceeding the reference number RN.

The memory controller 120 may perform a program operation using an increased program voltage in response to a program command for memory cells included in the first page PG1.

The magnitude of the voltage required for a program operation may decrease as a time interval between consecutive program operations decreases.

Accordingly, for example, the memory controller 120 may control the magnitude of the program voltage based on the threshold voltage distribution to decrease the program voltage by a magnitude corresponding to the required voltage magnitude as a time interval between consecutive program operations decreases.

For example, the memory controller 120 may control the program voltage by the magnitude corresponding to the required voltage magnitude according to a change in characteristics of the memory device 110, based on the threshold voltage distribution, to perform a program operation on the memory device 110.

The above-described configurations enable the storage device 100 according to one or more embodiments to improve the performance of program operations for the memory device 110.

Referring to FIGS. 17 and 18, the memory controller 120 according to one or more embodiments may control a read voltage for a read operation on a first page PG1 based on a threshold voltage distribution of memory cells included in the first page PG1.

In operation S60, the memory controller 120 according to one or more embodiments may apply the first read voltage Vr1 through a first wordline WL1 in response to a read command.

According to one or more embodiments, the first read voltage Vr1 may have a value corresponding to a prestored second voltage code. The second voltage code may be understood as a code stored in response to the number of off-cells OFCs exceeding a reference number RN.

The first read voltage Vr1 may have a value obtained by adding a unit read voltage Vur to the pre-read voltage Vr0 as described with reference to FIG. 12, for example. The pre-read voltage Vr0 may be understood as a voltage applied through the first wordline WL1 in a read operation performed before the program operation in operation S15. The unit read voltage Vur may be predetermined and stored in the memory device 110.

For example, the memory controller 120 may increase the read voltage for a read operation on the first page PG1 in response to the number of off-cells OFCs, among the memory cells included in the first page PG1, exceeding a reference number.

The above-described configurations enable the storage device 100 according to one or more embodiments to improve the performance of read operations for the memory device 110.

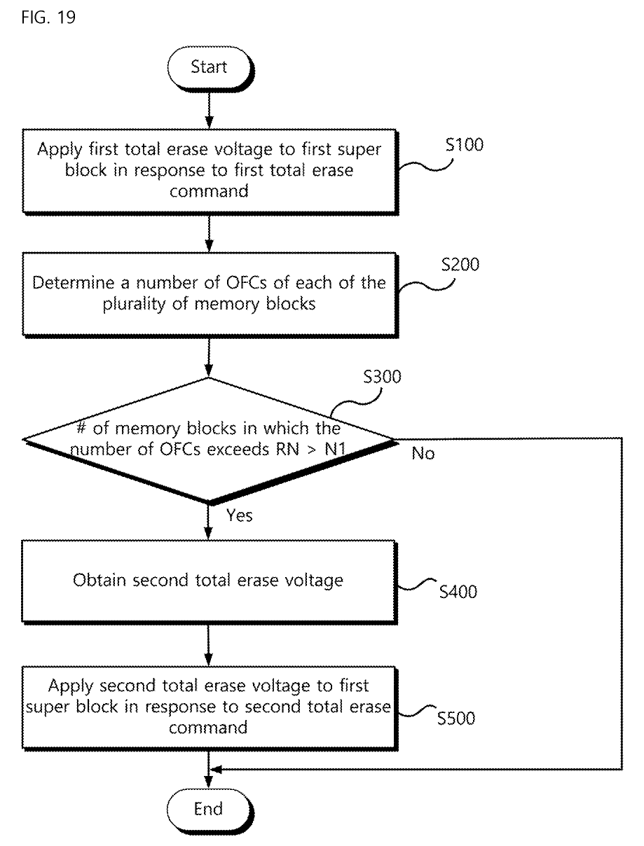

FIG. 19 is a flowchart illustrating a method, performed by a storage device according to one or more embodiments, of controlling the magnitude of a batch erase voltage applied to a super block based on threshold voltages of memory cells. FIG. 19 will be described with reference to FIGS. 13 and 14.

Referring to FIG. 19, the memory controller 120 according to one or more embodiments may control a batch erase voltage for a batch erase operation on a first super block SPB1 based on the threshold voltage distribution of memory cells included in the first super block SPB1.

According to one or more embodiments, the memory cell array 111 may include a plurality of super blocks SPB1 to SPBa, which are describe with reference to FIG. 13. The first super block SPB1 may include a plurality of memory blocks BLK1 to BLKb. Each of the super blocks excluding the first super block SPB1, among the plurality of super blocks SPB1 to SPBa, may include 'm' memory blocks.

Each of the plurality of super blocks SPB1 to SPBa may be a unit of an erase operation controlled by the memory controller 120. For example, the memory controller 120 may control a batch erase operation on each of the plurality of super blocks SPB1 to SPBa.

In operation S100, the memory controller 120 according to one or more embodiments may apply a first batch erase voltage Vte1 to the first super block SPB1 in response to a first batch erase command TEC1.

For example, the memory controller 120 may apply a first batch erase voltage Vte1 to each of the plurality of memory blocks BLK1 to BLKb included in the first super block SPB1 in response to the first batch erase command TEC1.

For example, the memory controller 120 may perform a batch erase operation on the first super block SPB1 in response to the first batch erase command TEC1.

The memory controller 120 may transition the threshold voltage distribution of memory cells included in the first super block SPB1 to an erased state in response to the first batch erase command TEC1.

In operation S200, the memory controller 120 according to one or more embodiments may determine the number of off-cells OFCs, each having a threshold voltage greater than or equal to a first reference voltage V1, in each of the plurality of memory blocks BLK1 to BLKb.

In operation S300, the memory controller 120 according to one or more embodiments may determine whether the number of memory blocks in which the number of off-cells OFCs exceeds a reference number RN, among the plurality of memory blocks BLK1 to BLKb, is greater than or equal to a first number N1. Each of the reference number RN and the first number N1 may be a predetermine value stored in the memory device 110.

In one example, a value of the first number N1 may be "1." For example, the memory controller 120 may determine whether the number of memory blocks in which the number of off-cells OFCs exceeds a reference number RN, among the plurality of memory blocks BLK1 to BLKb, is greater than or equal to 1.

In another example, the value of the first number N1 may be half of 'm', which represents a number of the memory blocks. For example, the memory controller 120 may determine whether the number of memory blocks in which the number of off-cells OFCs exceeds a reference number RN, among the plurality of memory blocks BLK1 to BLKb, is greater than or equal to half of ‘m’.

For example, the memory controller 120 may determine whether the number of memory blocks in which the number of off-cells OFCs each having a threshold voltage greater than or equal to the first reference voltage exceeds the reference number RN, among the plurality of memory blocks BLK1 to BLKb, exceeds the first number N1.

In operation S400, the memory controller 120 according to one or more embodiments may obtain a second batch erase voltage Vte2 in response to the number of memory blocks, in which the number of off-cells OFCs exceeds the reference number RN, being greater than or equal to the first number N1.

For example, the memory controller 120 may obtain a second batch erase voltage Vte2 by adding a unit erase voltage to a first batch erase voltage Vte1 in response to the number of memory blocks, in which the number of off-cells OFCs exceeds the reference number RN, being greater than or equal to the first number N1. A value of the unit erase voltage may be predetermined and stored in the memory device 110.

For example, the memory controller 120 may update a first voltage code corresponding to the first batch erase voltage Vte1 to a second voltage code corresponding to the second batch erase voltage Vte2 in response to the number of memory blocks, in which the number of off-cells OFCs exceeds the reference number RN, being greater than or equal to the first number N1.

For example, after an erase operation, when the number of memory blocks included in the first super block SPB1, in which the number of off-cells OFCs exceeds the reference number RN, is greater than or equal to the first number N1, the memory controller 120 may increase the batch erase voltage.

The memory controller 120 may store the value of the second batch erase voltage Vte2 or the second voltage code corresponding to the second batch erase voltage Vte2. For example, the memory controller 120 may store the value of the second batch erase voltage Vte2 or the second voltage code corresponding to the second batch erase voltage Vte2 in the memory device 110. For example, the memory controller 120 may store the value of the second batch erase voltage Vte2 or the second voltage code corresponding to the second batch erase voltage Vte2 in at least a portion of the plurality of memory blocks BLK1 to BLKn.

In operation S500, the memory controller 120 according to one or more embodiments may apply the second batch erase voltage Vte2 to the first super block SPB1.

For example, the memory controller 120 may apply the second batch erase voltage Vte2 to each of the plurality of memory blocks BLK1 to BLKb included in the first super block SPB1 in response to a second batch erase command TEC2. For example, the memory controller 120 may perform an erase operation on the first super block SPB1 using the second batch erase voltage Vte2 in response to the second batch erase command TEC2. For example, the memory controller 120 may apply a stored second batch erase voltage Vte2 to the first super block SPB1 in response to receiving the second batch erase command TEC2.

For example, after updating the erase voltage based on the threshold voltage distribution of the memory cells, the memory controller 120 may perform a batch erase operation using the updated batch erase voltage (for example, the second batch erase voltage Vte2) in response to a batch erase command (for example, a second batch erase command TEC2).

Referring to the above-described configurations, the memory controller 120 may determine whether the number of memory blocks, in which the number of off-cells OFCs exceeds the reference number RN, is greater than or equal to the first number N1 after performing an erase operation on the first super block SPB1.

The memory controller 120 may increase the batch erase voltage for a batch erase operation on the first super block SPB1 in response to the number of memory blocks, in which the number of off-cells OFCs exceeds the reference number RN, being greater than or equal to the first number N1.

The magnitude of the voltage required for a batch erase operation may increase as the time interval between consecutive program operations decreases.

Accordingly, for example, the memory controller 120 may control the magnitude of the batch erase voltage based on the threshold voltage distribution to increase the batch erase voltage by a magnitude corresponding to the voltage magnitude required as the time interval between consecutive program operations decreases.

For example, the memory controller 120 may control the batch erase voltage by a magnitude corresponding to the required voltage magnitude according to changes in characteristics of the memory device 110, based on the threshold voltage distribution, to perform a batch erase operation on the memory device 110.

Referring to the above-described configurations, the memory controller 120 according to one or more embodiments may control a batch erase voltage for the first super block SPB1 based on the threshold voltage distribution of the plurality of memory blocks BLK1 to BLKb.

Accordingly, the memory controller 120 may control the batch erase voltage within a relatively short time compared to the case in which the erase voltage for each of the plurality of memory blocks BLK1 to BLKb is individually controlled.

The above-described configurations enable the storage device 100C according to one or more embodiments to improve the performance of batch erase operations for the memory device 110.

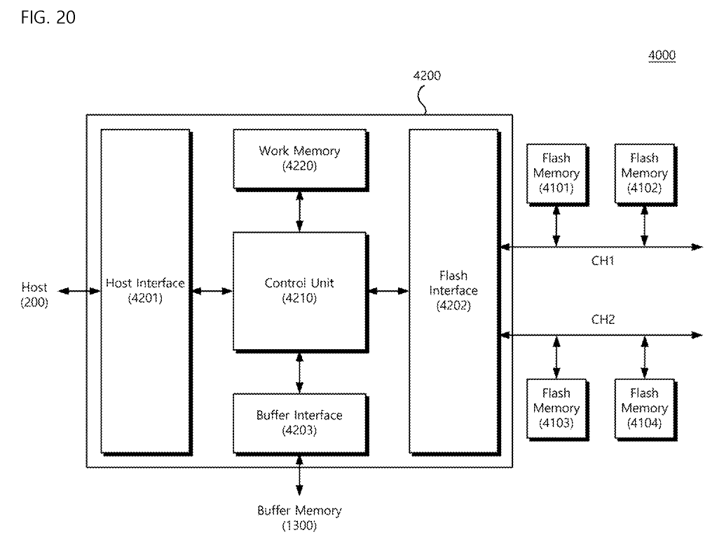

FIG. 20 is a block diagram illustrating an example of a storage device implemented as a solid state drive (SSD).

Referring to FIG. 20, an SSD 4000 may include a plurality of flash memories 4101 to 4104 and an SSD controller 4200. The SSD controller 4200 illustrated in FIG. 20 may be understood to be substantially the same in configuration as the memory controller 120 illustrated in FIG. 2.

A first flash memory 4101 and a second flash memory 4102 may be connected to the SSD controller 4200 through a first channel CH1. A third flash memory 4103 and a fourth flash memory 4104 may be connected to the SSD controller 4200 through a second channel CH2. The number of channels connected to the SSD controller 4200 may be greater than 2. The number of flash memories connected to one channel may be greater than 2.

The SSD controller 4200 may include a host interface 4201, a flash interface 4202, a buffer interface 4203, a control unit 4210, and a work memory 4220. The SSD controller 4200 may be connected to the host 200 via the host interface 4201. The SSD controller 4200 may write data to or read data from a corresponding flash memory at the request of the host 200.

The SSD controller 4200 may be connected to the plurality of flash memories 4101 to 4104 via the flash interface 4202, and may be connected to a buffer memory 1300 via the buffer interface 4203. The flash interface 4202 may provide data temporarily stored in the buffer memory 1300 to the flash memories through respective channels CH1, CH2. The flash interface 4202 may transfer data read from the flash memories 4101 to 4104 to the buffer memory 1300.

The control unit 4210 may analyze and process signals input from the host 200. The control unit 4210 may control the host 200 or the flash memories 4101 to 4104 through the host interface 4201 or the flash interface 4202. The control unit 4210 may control the operation of the flash memories 4101 to 4104 based on firmware for operating the SSD 4000.

The SSD controller 4200 may manage data to be stored in the flash memories 4101 to 4104. The SSD controller 4200 may back up data stored in the work memory 4220 or the buffer memory 1300 to the flash memories 4101 to 4104 during a sudden power-off operation.

According to one or more embodiments, after performing an erase operation on a specific memory block among the first flash memory 4101, the SSD controller 4200 may determine whether the number of off-cells OFCs, each having a threshold voltage greater than or equal to a reference voltage (for example, a first reference voltage V1), exceeds a reference number.

The SSD controller 4200 may increase the erase voltage for an erase operation on the corresponding memory block in response to the number of off-cells OFCs exceeding the reference number.

The magnitude of the voltage required for an erase operation may increase as the time interval between consecutive program operations decreases.

Accordingly, for example, the SSD controller 4200 may control the magnitude of the erase voltage based on the threshold voltage distribution to increase the erase voltage by a magnitude corresponding to the voltage magnitude required as the time interval between consecutive program operations decreases.

For example, the SSD controller 4200 may control the erase voltage by a magnitude corresponding to the required voltage magnitude according to changes in characteristics of the first flash memory 4101, based on the threshold voltage distribution, to perform an erase operation on the first flash memory 4101.

The above-described configurations enable the SSD 4000 according to one or more embodiments to improve the performance of operations (for example, an erase operation) on the first flash memory 4101.

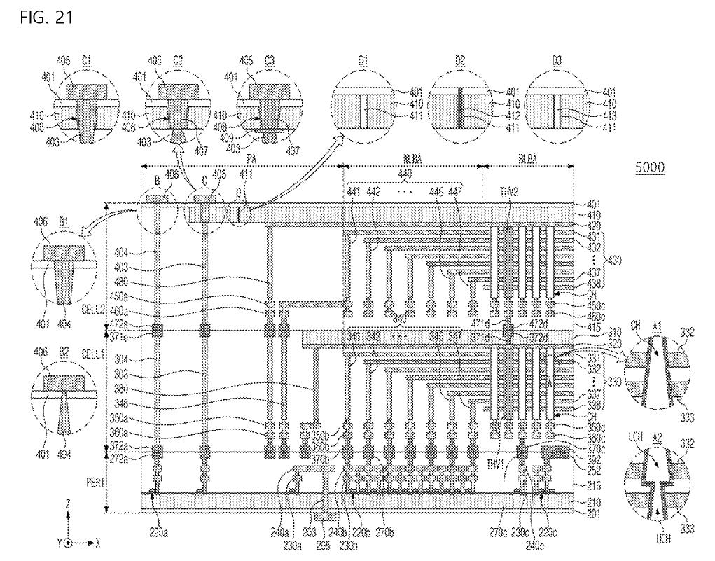

FIG. 21 is a diagram illustrating a flash memory according to one or more embodiments.

Referring to FIG. 21, a flash memory 5000 may have a chip-to-chip (C2C) structure. The C2C structure may refer to a structure in which at least one upper chip including a cell region CELL and at least one lower chip including a peripheral circuit region PERI are separately manufactured and then connected to each other by a bonding method. The flash memory 5000 illustrated in FIG. 21 may be understood to have substantially the same configuration as the memory device 110 illustrated in FIG. 2.

In one example, the bonding method may refer to a method of electrically or physically connecting bonding metal patterns formed on an uppermost metal layer of an upper chip and bonding metal patterns formed on an uppermost metal layer of a lower chip. For example, when the bonding metal patterns are formed of copper (Cu), the bonding method may be a Cu-Cu bonding method. In another example, the bonding metal patterns may be formed of aluminum (Al) or tungsten (W).

The flash memory 5000 may include at least one upper chip including a cell region. For example, as illustrated in FIG. 21, the flash memory 5000 may be implemented to include two upper chips. However, this is merely an example, and the number of upper chips is not limited thereto. When the flash memory 5000 is implemented to include two upper chips, the flash memory 5000 may be manufactured by first manufacturing a first upper chip including a first cell region CELL1, a second upper chip including a second cell region CELL2, and a lower chip including a peripheral circuit region PERI separately, and then connecting the first upper chip, the second upper chip, and the lower chip to each other by a bonding method. The first upper chip may be flipped and connected to the lower chip by a bonding method, and the second upper chip may also be flipped and connected to the first upper chip by a bonding method. In the following description, upper portions and lower portions of the first and second upper chips are defined based on before the first upper chip and the second upper chip are turned over. For example, in FIG. 21, an upper portion of the lower chip refers to an upper portion defined based on a positive Z-axis direction, and the upper portions of the first and second upper chips refer to upper portions defined based on a negative Z-axis direction. However, this is only an example, and only one of the first upper chip and the second upper chip may be flipped and connected by the bonding method.

Each of the peripheral circuit region PERI and the first and second cell regions CELL1 and CELL2 of the flash memory 5000 may include an external pad bonding region PA, a wordline bonding region WLBA, and a bitline bonding region BLBA.

The peripheral circuit region PERI may include a first substrate 210 and a plurality of circuit elements 220a, 220b, and 220c formed on the first substrate 210. An interlayer dielectric 215 including one or more dielectrics may be provided on the plurality of circuit elements 220a, 220b, and 220c, and a plurality of metal wirings connecting the plurality of circuit elements 220a, 220b, and 220c may be provided in the interlayer dielectric 215. For example, the plurality of metal wirings may include first metal wirings 230a, 230b, and 230c, respectively connected to the plurality of circuit elements 220a, 220b, and 220c, and second metal wirings 240a, 240b, and 240c formed on the first metal wirings 230a, 230b, 230c. The plurality of metal wirings may be formed of at least one of various conductive materials. For example, the first metal wirings 230a, 230b, and 230c may be formed of tungsten, which has a relatively high electrical resistivity, and the second metal wirings 240a, 240b, and 240c may be formed of copper, which has a relatively low electrical resistivity.

In the present disclosure, only the first metal wirings 230a, 230b, and 230c and the second metal wirings 240a, 240b, and 240c are illustrated and described, but embodiments are not limited thereto. At least one additional metal wiring may be further formed on the second metal wirings 240a, 240b, and 240c, and the second metal wirings 240a, 240b, and 240c may be formed of aluminum. At least a portion of the additional metal wirings formed on the second metal wirings 240a, 240b, and 240c may be formed of copper, or the like, which has a lower electrical resistivity than the aluminum of the second metal wirings 240a, 240b, and 240c.

The interlayer dielectric 215 may be disposed on the first substrate 210, and may include an insulating material such as silicon oxide, silicon nitride, or the like.

The first cell region CELL1 and the second cell region CELL2 may each include at least one memory block. The first cell region CELL1 may include a second substrate 310 and a common source line 320. A plurality of wordlines 331 to 338 (330) may be stacked in a direction (Z-axis direction), perpendicular to an upper surface of the second substrate 310, on the second substrate 310. String select lines and ground select lines may be disposed above and below the wordlines 330, and a plurality of wordlines 330 may be disposed between the string select lines and the ground select lines. Similarly, the second cell region CELL2 may include a third substrate 410 and a common source line 420, and a plurality of wordlines 431 to 438 (430) may be stacked in a direction (Z-axis direction), perpendicular to the upper surface of the third substrate 410. Each of the second substrate 310 and the third substrate 410 may be formed of various materials and may be, for example, a silicon substrate, a silicon-germanium substrate, a germanium substrate, or a substrate having a single-crystal epitaxial layer grown on a single-crystal silicon substrate. A plurality of channel structures CH may be formed in each of the first cell region CELL1 and the second cell region CELL2.

In one or more embodiments, as illustrated in A1, the channel structure CH is provided in the bitline bonding region BLBA and extends in a direction perpendicular to the upper surface of the second substrate 310, and may penetrate the wordlines 330, the string select lines, and the ground select lines. The channel structure CH may include a data storage layer, a channel layer, an embedded insulating layer, or the like. The channel layer may be electrically connected to a first metal wiring 350c and a second metal wiring 360c in the bitline bonding region BLBA. For example, the second metal wiring 360c may be a bitline and may be connected to the channel structure CH through the first metal wiring 350c. The bitline 360c may extend in a first direction (Y-axis direction) parallel to the upper surface of the second substrate 310.

In one or more embodiments, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in a direction perpendicular to the upper surface of the second substrate 310 and may penetrate through the common source line 320 and the lower wordlines 331 and 332. The lower channel LCH may include a data storage layer, a channel layer, a buried insulating layer, or the like, and may be connected to the upper channel UCH. The upper channel UCH may penetrate through the upper wordlines 333 to 338. The upper channel UCH may include a data storage layer, a channel layer, an embedded insulating layer, and the like, and the channel layer of the upper channel UCH may be electrically connected to the first metal wiring 350c and the second metal wiring 360c. As the length of the channel increases, it may become difficult to form a channel having a uniform width due to process reasons. The flash memory 5000 according to one or more embodiments may include a channel with improved width uniformity through the lower channel LCH and the upper channel UCH formed by sequential processes.

When the channel structure CH is formed to include a lower channel LCH and an upper channel UCH as illustrated in A2, the wordline disposed near the boundary of the lower channel LCH and the upper channel UCH may be a dummy wordline. For example, the wordline 332 and the wordline 333 forming the boundary between the lower channel LCH and the upper channel UCH may be dummy wordlines. Data may not be stored in the memory cells connected to the dummy wordlines. Alternatively, the number of pages corresponding to the memory cells connected to the dummy wordlines may be smaller than the number of pages corresponding to the memory cells connected to normal wordlines. The level of a voltage applied to the dummy wordline may be different from the level of a voltage applied to a normal wordline, thereby reducing the effect of a non-uniform channel width between the lower channel LCH and the upper channel UCH on the operation of the flash memory.

In A2, the number of lower wordlines 331 and 332 that the lower channel LCH penetrates through is illustrated as being smaller than the number of upper wordlines 333 to 338 that the upper channel UCH penetrates through. However, this is merely an example, and embodiments are not limited thereto. In another example, the number of lower wordlines that the lower channel LCH penetrates through may be the same as or greater than the number of upper wordlines that the upper channel UCH penetrates through. The above-described structure and connection relationship of the channel structure CH disposed in the first cell region CELL1 may be similarly applied to the channel structure CH disposed in the second cell region CELL2.

In the bitline bonding region BLBA, a first through-electrode THV1 may be provided in the first cell region CELL1, and a second through-electrode THV2 may be provided in the second cell region CELL2. As illustrated in FIG. 21, the first through-electrode THV1 may penetrate through the common source line 320 and the plurality of wordlines 330. However, this is merely an example, and the first through-electrode THV1 may further penetrate through the second substrate 310. The first through-electrode THV1 may include a conductive material. Alternatively, the first through-electrode THV1 may include a conductive material surrounded by an insulating material. The second through-electrode THV2 may also be provided with the same shape and structure as the first through-electrode THV1.

In one or more embodiments, the first through-electrode THV1 and the second through-electrode THV2 may be electrically connected through a first through-metal pattern 372d and a second through-metal pattern 472d. The first through-metal pattern 372d may be formed at a lower end of a first upper chip including the first cell region CELL1, and the second through-metal pattern 472d may be formed at an upper end of a second upper chip including the second cell region CELL2. The first through-electrode THV1 may be electrically connected to the first metal wiring 350c and the second metal wiring 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected using a bonding method.

In the bitline bonding region BLBA, an upper metal pattern 252 may be formed on an uppermost metal layer of the peripheral circuit region PERI, and an upper metal pattern 392 having the same shape as the upper metal pattern 252 may be formed on an uppermost metal layer of the first cell region CELL1. The upper metal pattern 392 of the first cell region CELL1 and the upper metal pattern 252 of the peripheral circuit region PERI may be electrically connected to each other using a bonding method. In the bitline bonding region BLBA, the bitline 360c may be electrically connected to a page buffer included in the peripheral circuit region PERI. For example, a portion of circuit elements 220c of the peripheral circuit region PERI may provide a page buffer, and the bitline 360c may be electrically connected to the circuit elements 220c providing the page buffer through an upper bonding metal 370c of the first cell region CELL1 and an upper bonding metal 270c of the peripheral circuit region PERI.

Continuing to refer to FIG. 21, in the wordline bonding region WLBA, the wordlines 330 of the first cell region CELL1 may extend in a second direction (X-axis direction) parallel to the upper surface of the second substrate 310, and may be connected to a plurality of cell contact plugs 341 to 347 (340). A first metal wiring 350b and a second metal wiring 360b may be connected sequentially above the cell contact plugs 340 connected to the wordlines 330. The cell contact plugs 340 may be connected to the peripheral circuit region PERI through an upper bonding metal 370b of the first cell region CELL1 and an upper bonding metal 270b of the peripheral circuit region PERI in the wordline bonding region WLBA.

The cell contact plugs 340 may be electrically connected to an address decoder included in the peripheral circuit region PERI. For example, a portion of the circuit elements 220b of the peripheral circuit region PERI may provide an address decoder, and the cell contact plugs 340 may be electrically connected to the circuit elements 220b providing an address decoder through an upper bonding metal 370b of the first cell region CELL1 and an upper bonding metal 270b of the peripheral circuit region PERI. In one or more embodiments, the operating voltage of the circuit elements 220b providing the address decoder may be different from the operating voltage of the circuit elements 220c providing the page buffer. For example, the operating voltage of the circuit elements 220c providing the page buffer may be greater than the operating voltage of the circuit elements 220b providing the address decoder.

Similarly, in the wordline bonding region WLBA, the wordlines 430 of the second cell region CELL2 may extend along a second direction (X-axis direction) parallel to the upper surface of the third substrate 410, and may be connected to a plurality of cell contact plugs 441-447 (440). The cell contact plugs 440 may be connected to the peripheral circuit region PERI through an upper metal pattern of the second cell region CELL2, lower and upper metal patterns of the first cell region CELL1, and a cell contact plug 348.

In the wordline bonding region WLBA, an upper bonding metal 370b may be formed in the first cell region CELL1, and an upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metals 370b and 270b may be formed of aluminum, copper, or tungsten.

In the external pad bonding region PA, a lower metal pattern 371e may be formed at the bottom of the first cell region CELL1, and an upper metal pattern 472a may be formed at the top of the second cell region CELL2. The lower metal pattern 371e of the first cell region CELL1 and the upper metal pattern 472a of the second cell region CELL2 may be connected using a bonding method in the external pad bonding region PA. Similarly, an upper metal pattern 372a may be formed on the first cell region CELL1, and an upper metal pattern 272a may be formed on the peripheral circuit region PERI. The upper metal pattern 372a of the first cell region CELL1 and the upper metal pattern 272a of the peripheral circuit region PERI may be connected using a bonding method.

Common source line contact plugs 380 and 480 may be disposed in the external pad bonding region PA. The common source line contact plugs 380 and 480 may be formed of a conductive material such as metal, metal compound, or doped polysilicon. A common source line contact plug 380 of the first cell region CELL1 may be electrically connected to a common source line 320, and a common source line contact plug 480 of the second cell region CELL2 may be electrically connected to a common source line 420. A first metal wiring 350a and a second metal wiring 360a may be sequentially stacked on the common source line contact plug 380 of the first cell region CELL1, and a first metal wiring 450a and a second metal wiring 460a may be sequentially stacked on the common source line contact plug 480 of the second cell region CELL2.

Input/output pads 205, 405, and 406 may be disposed in the external pad bonding region PA. Referring to FIG. 21, a lower insulating layer 201 may cover the lower surface of the first substrate 210, and a first input/output pad 205 may be formed on the lower insulating layer 201. The first input/output pad 205 may be connected to at least one of the plurality of circuit elements 220a disposed in the peripheral circuit region PERI through a first input/output contact plug 203, and may be separated from the first substrate 210 by the lower insulating layer 201. A side insulating layer may be disposed between the first input/output contact plug 203 and the first substrate 210 to electrically separate the first input/output contact plug 203 and the first substrate 210.

An upper insulating layer 401 covering the upper surface of the third substrate 410 may be formed on the third substrate 410. A second input/output pad 405 and/or a third input/output pad 406 may be disposed on the upper insulating layer 401. The second input/output pad 405 is connected to at least one of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

In one or more embodiments, the third substrate 410 may not be disposed in the region in which the input/output contact plug is disposed. For example, as illustrated in B, the third input/output contact plug 404 is separated from the third substrate 410 in a direction parallel to the upper surface of the third substrate 410, and may penetrate through the interlayer dielectric 415 of the second cell region CELL2 to be connected to the third input/output pad 406. The third input/output contact plug 404 may be formed by various processes.

For example, as illustrated in B1, the third input/output contact plug 404 may extend in a third direction (Z-axis direction) and may be formed to have a diameter increasing in a direction towards the upper insulating layer 401. For example, the diameter of the channel structure CH described in A1 decrease in a direction towards the upper insulating layer 401, while the diameter of the third input/output contact plug 404 may increase in a direction towards the upper insulating layer 401. For example, the third input/output contact plug 404 may be formed after the second cell region CELL2 and the first cell region CELL1 are bonded together.

For example, as illustrated in B2, the third input/output contact plug 404 may extend in a third direction (Z-axis direction), and may be formed to have a diameter decreasing in a direction towards the upper insulating layer 401. For example, the third input/output contact plug 404 may be formed to have a diameter decreasing in a direction towards the upper insulating layer 401, similarly to the channel structure CH. For example, the third input/output contact plug 404 may be formed along with the cell contact plugs 440 before the bonding of the second cell region CELL2 and the first cell region CELL1.

In one or more embodiment, the input/output contact plug may be disposed to overlap the third substrate 410. For example, as illustrated in C, the second input/output contact plug 403 is formed to penetrate through the interlayer dielectric 415 of the second cell region CELL2 in the third direction (Z-axis direction), and may be electrically connected to the second input/output pad 405 through the third substrate 410. The connection structure of the second input/output contact plug 403 and the second input/output pad 405 may be implemented in various ways.

For example, as illustrated in C1, an opening 408 may be formed to penetrate through the third substrate 410, and the second input/output contact plug 403 may be directly connected to the second input/output pad 405 through the opening 408 formed in the third substrate 410. As illustrated in C1, the second input/output contact plug 403 may be formed to have a diameter increasing in a direction towards the second input/output pad 405. However, this is merely an example, and the second input/output contact plug 403 may also be formed to have a diameter decreasing in a direction towards the second input/output pad 405.

For example, as illustrated in C2, an opening 408 may be formed to penetrate through the third substrate 410, and a contact 407 may be formed within the opening 408. One end portion of the contact 407 may be connected to the second input/output pad 405, and another end portion thereof may be connected to the second input/output contact plug 403. Accordingly, the second input/output contact plug 403 may be electrically connected to the second input/output pad 405 through the contact 407 in the opening 408. As illustrated in C2, the diameter of the contact 407 may increase in a direction towards the second input/output pad 405, and the diameter of the second input/output contact plug 403 may decrease in a direction towards the second input/output pad 405. For example, the second input/output contact plug 403 may be formed along with the cell contact plugs 440 before the bonding of the second cell region CELL2 and the first cell region CELL1, and the contact 407 may be formed after the bonding of the second cell region CELL2 and the first cell region CELL1.

For example, as illustrated in C3, a stopper 409 may be further formed on the upper surface of the opening 408 of the third substrate 410 compared to C2. The stopper 409 may be a metal wiring formed on the same layer as the common source line 420. However, this is merely an example, and the stopper 409 may also be a metal wiring formed on the same layer as at least one of the wordlines 430. The second input/output contact plug 403 may be electrically connected to the second input/output pad 405 through the contact 407 and the stopper 409.

Similarly to the second and third input/output contact plugs 403 and 404 of the second cell region CELL2, each of the second and third input/output contact plugs 303 and 304 of the first cell region CELL1 may be formed to have a diameter decreasing in a direction towards the lower metal pattern 371e, or a diameter increasing in a direction towards the lower metal pattern 371e.

According to one or embodiments, a slit 411 may be formed in the third substrate 410. For example, the slit 411 may be formed at any location in the external pad bonding region PA. In one example, as illustrated in D, the slit 411 may be disposed between the second input/output pad 405 and the cell contact plugs 440 when viewed in a plan view. However, this is merely an example, and the slit 411 may be formed such that the second input/output pad 405 is disposed between the slit 411 and the cell contact plugs 440 when viewed in a plan view.

For example, as illustrated in D1, the slit 411 may be formed to penetrate through the third substrate 410. The slit 411 may be used, for example, to prevent fine cracking of the third substrate 410 when the opening 408 is formed. However, this is merely an example, and the slit 411 may be formed to have a depth of about 60 to 70 % of the thickness of the third substrate 410.

For example, as illustrated in D2, a conductive material 412 may be formed within the slit 411. A conductive material 412 may be used, for example, to discharge leakage current, generated during the operation of circuit elements within the external pad bonding region PA, to an external entity. The conductive material 412 may be connected to an external ground line.

For example, as illustrated in D3, an insulating material 413 may be formed within the slit 411. An insulating material 413 may be formed, for example, to electrically isolate the second input/output pad 405 and the second input/output contact plug 403, disposed in the external pad bonding region PA, from the wordline bonding region WLBA. Forming the insulating material 413 within the slit 411 may prevent a voltage supplied through the second input/output pad 405 from affecting the metal layer disposed on the third substrate 410 within the wordline bonding region WLBA.

According to one or more embodiments, the first to third input/output pads 205, 405, and 406 may be selectively formed. For example, the flash memory 5000 may be implemented to include only the first input/output pad 205 disposed on the first substrate 210, or only the second input/output pad 405 disposed on the third substrate 410, or only the third input/output pad 406 disposed on the upper insulating layer 401.

According to one or more embodiments, at least one of the second substrate 310 of the first cell region CELL1 and the third substrate 410 of the second cell region CELL2 may be used as a sacrificial substrate, and may be completely or partially removed before or after the bonding process. An additional layer may be stacked after the substrate removal. For example, the second substrate 310 of the first cell region CELL1 may be removed before or after the bonding of the peripheral circuit region PERI and the first cell region CELL1, and an insulating layer covering the upper surface of the common source line 320 or a conductive layer for connection may be formed. Similarly, the third substrate 410 of the second cell region CELL2 may be removed before or after the bonding of the first cell region CELL1 and the second cell region CELL2, and an upper insulating layer 401 covering the upper surface of the common source line 420 or a conductive layer for connection may be formed.

As described above, the memory controller 120 according to one or more embodiments may determine whether the number of off-cells OFCs, each having a threshold voltage greater than or equal to a reference voltage (for example, a first reference voltage V1), exceeds a reference number after performing an erase operation on a first memory block BLK1.

The memory controller 120 may increase the erase voltage for an erase operation on the first memory block BLK1 in response to the number of off-cells OFCs exceeding the reference number.

The magnitude of the voltage required for an erase operation may increase as the time interval between consecutive program operations decreases.

Accordingly, for example, the memory controller 120 may control the magnitude of the erase voltage based on the threshold voltage distribution to increase the erase voltage by a magnitude corresponding to the required voltage magnitude as the time interval between consecutive program operations decreases.

For example, the memory controller 120 may control the erase voltage by a magnitude corresponding to the required voltage magnitude according to a change in characteristics of the memory device 110, based on the threshold voltage distribution, to perform an erase operation on the memory device 110.

The magnitude of the voltage required for a program operation may decrease as the time interval between consecutive program operations decreases.

Accordingly, for example, the memory controller 120 may control the magnitude of the program voltage based on the threshold voltage distribution to decrease the program voltage by a magnitude corresponding to the voltage magnitude required as the time interval between consecutive program operations decreases.

In addition, the memory controller 120 may control the read voltage by a magnitude corresponding to the required voltage magnitude according to changes in characteristics of the memory device 110, based on the threshold voltage distribution, to perform a read operation on the memory device 110.

The above-described configurations enable the storage device 100 according to one or more embodiments to improve the performance of operations (for example, an erase operation, a program operation, or a read operation) on the memory device 110.

As set forth above, according to embodiments, the performance of operations on a memory device may be improved.

While various embodiments have been shown and described above, it will be apparent to those skilled in the art that modifications and variations could be made without departing from the scope of the present inventive concept as defined by the appended claims.

What is claimed is:

1. A method of operating a storage device, the method comprising:
applying a first erase voltage to a first memory block, among a plurality of memory blocks, in response to a first erase command for the first memory block;
determining a number of off-cells, each having a threshold voltage greater than or equal to a reference voltage, among memory cells included in the first memory block;
obtaining a second erase voltage by adding a unit erase voltage to the first erase voltage in response to the number of the off-cells exceeding a reference number; and
applying the second erase voltage to the first memory block in response to a second erase command for the first memory block.

2. The method of claim 1,
wherein the determining of the number of the off-cells among the memory cells comprises:
determining the number of the off-cells, each having a threshold voltage greater than or equal to a first reference voltage, among memory cells erased by the first erase voltage.

3. The method of claim 1,
wherein the determining of the number of the off-cells among the memory cells further comprises:
applying a first program voltage through a first wordline connected to a first page to at least a portion of memory cells, in an erased state, included in the first page in the first memory block, in response to a first program command for the first page; and
determining the number of the off-cells, each having a threshold voltage greater than or equal to a second reference voltage, among the portion of the memory cells included in the first page,
wherein the portion of the memory cells are programmed by the first program voltage.

4. The method of claim 3,
wherein the obtaining of the second erase voltage comprises:
obtaining the second erase voltage in response to the number of the off-cells, each having a threshold voltage greater than or equal to the second reference voltage, exceeding the reference number.

5. The method of claim 3, further comprising:
applying a second program voltage, obtained by subtracting a unit program voltage from the first program voltage to the first wordline in response to a second program command for the memory cells included in the first page after applying the second erase voltage to the first memory block.

6. The method of claim 3, further comprising:
storing a voltage code corresponding to the second erase voltage in at least a portion of the plurality of memory blocks in response to obtaining the second erase voltage.

7. The method of claim 6, further comprising:
applying a first read voltage corresponding to the voltage code to the first wordline in response to a read command for the memory cells included in the first page after storing the voltage code.

8. The method of claim 1, further comprising:
applying a first batch erase voltage to memory cells included in each of the plurality of memory blocks in response to a first batch erase command for the plurality of memory blocks;
obtaining a second batch erase voltage by adding the unit erase voltage to the first batch erase voltage when a number of memory blocks in which the number of the off-cells exceeds the reference number, among the plurality of memory blocks, is greater than or equal to a first number; and
applying the second batch erase voltage to the memory cells included in each of the plurality of memory blocks in response to a second batch erase command for the plurality of memory blocks.

9. The method of claim 1, further comprising:
adjusting a magnitude of the reference voltage in response to a temperature, at which the storage device operates, being lower than or equal to a predetermined threshold temperature.

10. The method of claim 1, further comprising:
determining a number of off-cells each having a threshold voltage greater than or equal to the reference voltage, among the memory cells, in response to an erase operation being performed on the first memory block a predetermined number of times using the second erase voltage; and
obtaining a third erase voltage by adding the unit erase voltage to the second erase voltage in response to the number of the off-cells exceeding the reference number among the memory cells erased by the second erase voltage.

11. A storage device comprising:
a memory device comprising a plurality of memory blocks; and
a memory controller configured to control an erase operation, a program operation, and a read operation on the memory device,
wherein the memory controller is configured to:
apply a first erase voltage to memory cells included in a first memory block in response to a first erase command for the first memory block;
determine a number of off-cells, each having a threshold voltage greater than or equal to a reference voltage, among the memory cells;
obtain a second erase voltage by adding a unit erase voltage to the first erase voltage in response to the number of the off-cells exceeding a reference number; and
apply the second erase voltage to the memory cells in response to a second erase command for the first memory block.

12. The storage device of claim 11, wherein the memory controller is configured to determine the number of the off-cells, each having a threshold voltage greater than or equal to a first reference voltage, among the memory cells erased by the first erase voltage.

13. The storage device of claim 11,
wherein the memory controller is configured to:
applying a first program voltage to at least a portion of memory cells, in an erased state, through a first wordline connected to the first page in response to a first program command for memory cells included in a first page in the first memory block; and
determine the number of the off-cells, each having a threshold voltage greater than or equal to a second reference voltage, among the portion of the memory cells in the first page, the portion of the memory cells being programmed by the first program voltage.

14. The storage device of claim 13,
wherein the memory controller is configured to:
obtain a second program voltage by subtracting a unit program voltage from the first program voltage in response to the number of the off-cells exceeding the reference number; and
apply the second program voltage through the first wordline in response to a second program command for the memory cells included in the first page.

15. The storage device of claim 11,
wherein the memory controller is configured to store a voltage code corresponding to the second erase voltage in the memory device in response to obtaining the second erase voltage.

16. A method of operating a storage device, the method comprising:
applying a first erase voltage to memory cells included in a first memory block among a plurality of memory blocks in response to a first erase command for the first memory block;
applying a first program voltage through a first wordline connected to a first page to memory cells included in the first page in the first memory block in response to a first program command for the first page;
determining a number of off-cells, each having a threshold voltage greater than or equal to a reference voltage, among the memory cells included in the first memory block;
obtaining a second program voltage by subtracting a unit program voltage from the first program voltage in response to the number of the off-cells exceeding a reference number; and
applying the second program voltage through the first wordline in response to a second program command for the memory cells included in the first page.

17. The method of claim 16,
wherein the determining of the number of the off-cells further comprises:
determining the number of the off-cells, each having a threshold voltage greater than or equal to a first reference voltage, among memory cells in an erased state.

18. The method of claim 16,
wherein the determining of the number of the off-cells comprises:
determining the number of the off-cells, each having a threshold voltage greater than or equal to a second reference voltage, among memory cells programmed by the first program voltage.

19. The method of claim 18, further comprising:
obtaining a second erase voltage by adding a unit erase voltage to the first erase voltage in response to the number of the off-cells exceeding the reference number; and
applying the second erase voltage to the memory cells included in the first memory block in response to a second erase command for the first memory block.

20. The method of claim 19, further comprising:
determining a number of off-cells, each having a threshold voltage greater than or equal to the reference voltage, among the memory cells in response to an erase operation being performed on the first memory block a predetermined number of times using the second erase voltage; and
obtaining a third erase voltage by adding the unit erase voltage to the second erase voltage in response to the number of the off-cells exceeding the reference number among the memory cells erased by the second erase voltage.
